(19) United States
(12) Patent Application Publication
(10) Pub. No.: US 2012/0327580 A1
(43) Pub. Date: Dec. 27, 2012

(54) PROTECTIVE DEVICES AND SYSTEMS FOR PORTABLE ELECTRONIC DEVICES AND ASSOCIATED METHODS

(75) Inventor: David P. Gengler, Draper, UT (US)

(73) Assignee: ZAGG INTELLECTUAL PROPERTY HOLDING CO., INC., Salt Lake City, UT (US)

(21) Appl. No.: 13/532,767

(22) Filed: Jun. 25, 2012

Related U.S. Application Data
(60) Provisional application No. 61/503,595, filed on Jun. 30, 2011.
(60) Provisional application No. 61/500,568, filed on Jun. 23, 2011.

(51) Int. Cl. H05K 7/00; H05K 5/00; H05K 13/00

(52) U.S. Cl. 361/679.09; 29/592.1; 174/50

(57) ABSTRACT

A protective system is configured to protect a display, screen and/or housing of a portable electronic device while the device is not in use. The protective system also may connect to an accessory providing input/output functions for the portable electronic device. The accessory may provide a support element configured to orient and support the portable electronic device in a working orientation that is inclined relative to the accessory. The support element may include an elongated recess into which an end portion of the portable electronic device may be positioned. Such a channel may be at an incline and/or may be sized such that the portable electronic device is at a leveraged position within the channel such that the support element can support the portable electronic device in the working arrangement even in the absence of supplement support elements.

### CROSS-REFERENCE TO RELATED APPLICATIONS

This application claims the benefit of priority under 35 U.S.C. §119(e) to U.S. Provisional Patent Application No. 61/503,595, filed on Jun. 30, 2011, pending, and to U.S. Provisional Patent Application No. 61/500,568, filed on Jun. 23, 2012, the entire disclosures of both of which are, by this reference, hereby incorporated herein.

### TECHNICAL FIELD

The present disclosure relates generally to devices for carrying, supporting and/or protecting portable electronic devices. More particularly, aspects of the present disclosure relate to accessories for portable electronic devices and systems integrated with peripheral components that enhance or supplement the functionality of portable electronic devices, such as keyboards, for supporting portable electronic devices in an at least partially upright, or inclined, orientation. When a display, screen, or housing of a portable electronic device is supported by a support device or other accessory, the display may be maintained at least partially upright, thereby enabling a user to view or otherwise use the display, screen, or device while optionally using the peripheral component. The present disclosure further relates to covers for protecting portable electronic devices. When positioned over the display of a portable electronic device, a protective cover of the present disclosure may provide protection and, optionally, provides protection without substantially increasing the thickness, width and/or length of the portable electronic device.

### RELATED ART

Since the advent of mobile computing, efforts have been made to improve the ease with which portable electronic devices may be used, the speeds at which portable electronic devices operate and the availability and quality of wireless network services, as well as to expand the functionality of portable electronic devices. The frequency with which portable electronic devices are used, and the circumstances and locations where portable electronic devices are used, are ever-increasing. In fact, users who carry portable electronic devices often access them many times throughout each day and at multiple locations.

The portability of state-of-the art electronic devices that are configured for use in mobile computing has largely been made possible by advances in technology that enable all of the components of a portable electronic device to be assembled into relatively small, lightweight packages. Many portable electronic devices, such as so-called “smart phones,” are configured to be carried in a pocket of an individual's clothing, in a carrying case or in a handbag, backpack or the like. Other mobile computing devices, such as so-called “tablet” or “slate” computers, are also configured to be carried within carrying cases, folios, handbags, backpacks or the like.

Because of the small sizes of state-of-the-art portable electronic devices, the user interface features that enable an individual to enter information into the device are also relatively small. For example, some mobile computing devices include small dedicated input devices, such as keyboards and the like. Regardless of their size, however, small dedicated input devices consume valuable space, decreasing the available display area of an electronic device or adding to the thickness of the electronic device. Furthermore, the smaller the input device, the more difficult it is to use, which may decrease the speed with which an individual may use the input device.

Other electronic devices include touch sensitive displays, which provide both output capabilities and input capabilities. Touch sensitive displays eliminate the need for actual buttons while enabling the maximization of display sizes. When input functions are required or wanted, a touch screen may display a virtual keyboard. By touching the display at appropriate locations on the virtual keyboard, an individual may type in a manner similar to that employed while using a keyboard with actual buttons. While touch sensitive displays that enable the generation and use of virtual keyboards may enable minimization of the size of an electronic device, when a virtual keyboard is needed or desired, it typically consumes a significant portion of area of the display, leaving a much smaller viewing area. Although they may maximize display sizes, virtual keyboards may be difficult to use, and certain users may find their lack of tactile response, or haptic feedback, undesirable. Furthermore, small virtual keyboards may increase the likelihood of typing errors and the difficulty in correcting such errors.

In an effort to overcome the shortcomings of small input devices and virtual input devices, a variety of accessories that enhance or supplement the functionality of electronic devices have been developed. These accessories may, for instance, communicate with many state-of-the-art electronic devices by way of one or more wireless protocols (e.g., the BLUETOOTH® open wireless technology standard, an infrared communication protocol, etc.). In cases where the accessories comprise keyboards, the keyboards may be foldable, flexible, or have a reduced size (e.g., width or thickness) to impart them with a desired degree of portability.

A user of an electronic device (e.g., a tablet, e-reader, smart phone, etc.) may occasionally use the electronic device in connection with a stand. The stand may receive and support the electronic device at an inclined angle, which may eliminate the need for an individual to hold the electronic device in the desired orientation. A stand may orient the display of an electronic device in such a way that an individual can view the display while using a separate accessory, such as a keyboard, to interface with the electronic device.

When the keyboard, portable electronic device, and stand are not in use, each component can be stored separately, or they can be slipped into one or more compartments of a storage case or carrying case, a folio or a handbag, backpack or the like. As the accessory and support are separate from one another, they can consume an undesirably large amount of storage space, and they may be easily separated from one another. As conventional peripheral keyboards are typically not configured for assembly with portable electronic devices during storage, carrying a portable keyboard with a portable electronic device can significantly increase the storage space required for the entire system.

Further, with repeated access and use, the potential for dropping or otherwise damaging fragile portable electronic devices and/or accessories is significant. Although such devices may be considered to be relatively affordable by historical standards, the monetary costs of portable electronic devices and corresponding accessories are still significant, particularly for many individual consumers. In addition, the repair or replacement of damaged portable electronic devices, and the restoration of data and applications (i.e., programs), require significant amounts of valuable time.

### SUMMARY

A protective system that incorporates teachings of the present disclosure is configured to be optionally utilized in connection with an accessory that can provide power, data, or other input or output to a portable electronic device. A protective system of the present disclosure may be configured to provide support the portable electronic device in an upright, working arrangement while allowing the portable electronic device to also be positioned in a closed, storage or protected arrangement in which a display, housing or other aspects of the portable electronic device are protected from damage or excess wear and tear.

In various embodiments, a protective system of the present disclosure includes a protective device which is configured to selectively support the portable electronic device and to be selectively positioned in the protected arrangement over the display of a portable electronic device. The protective device may include a base and one or more retention elements that may operate in concert with one another to define a receptacle into which the portable electronic device may be positioned. In the protected arrangement, the one or more retention elements may engage portions of the outer periphery of the portable electronic device and optionally absorb impact against at least the covered portion of the periphery of the device. While in the protected arrangement, the display of the portable electronic device may be covered and protected from damage.

In addition to the protective device, an accessory may be removably connected to, or otherwise associated with, the protective device. The accessory can include a support element configured to support the electronic device in the working arrangement (e.g., perpendicular to the accessory, at a non-perpendicular angle to the accessory, etc.). The support element may include an elongated recess, such as a groove or channel, into which a portion of the portable electronic device may be inserted. Optionally, a surface defining the oriented to orient the portable electronic device at a non-perpendicular angle or it may be oversized so as to enable the portable electronic device to also be placed in the desired working arrangement with respect to the accessory. The support element may hold the portable electronic device in the working arrangement even in the absence of supplemental external support elements separate from the accessory and/or protective device. Retention of the portable electronic device in the working arrangement may be enabled by leveraging the portable electronic device within the elongated recess. In some embodiments, the elongated recess may substantially support the portable electronic device without any moving parts, such as stands.

A protective system according to embodiments of the present disclosure may be configured for use with a particular portable electronic device, or for use with any number of different portable electronic devices. A protective device of a protective system may, for instance, include a protective shell that includes access features (e.g., slots, openings, etc.) configured to provide access to one or more components of the accessory (e.g., antennas, communication ports, speakers, power supply, etc.). Access features may additionally, or alternatively, provide access to components of a particular style of a portable electronic device. Specifically located features such as cameras, card readers, communication ports, speakers, and the like may each be positioned to coincide with a corresponding access feature in the protective device.

A support element may also be specific to a particular device or intended for wider use. A elongated recess of a support element may, for instance, have a length corresponding to a maximum dimension of a particular type of portable electronic device and/or a width slightly greater than a thickness of that type of portable electronic device. The elongated recess may be closed at both ends to define its length. In other embodiments, the elongated recess may be configured for use with a plurality of different types and/or sizes of portable electronic devices. In such case, the elongated recess may be open at one or more sides of the accessory so that a larger portable electronic device may extend partially outside of the elongated recess while remaining supported by the accessory.

Without limiting the scope of the present disclosure, an accessory of a protective system may include a peripheral component, such as keyboard. The keyboard may be a physical, or tangible, keyboard that is easier to use than virtual keyboards on a touch screen, or which may be used without occupying any of the display area. Other non-limiting examples of peripheral components include power supplies, such as batteries that may provide backup power for a portable electronic device; communication elements that may provide a portable electronic device with alternate and/or additional means of communication (e.g., USB ports, USB micro ports, HDMI ports, IEEE 1394 jacks, etc.); peripheral memory devices (e.g., optical drives, hard drives, etc.); and other accessories that may enhance or extend the functionality of a portable electronic device.

The protective system may include an accessory that is fixedly secured to a protective device, and in a manner such that the accessory is not intended for quick removal and/or replacement. The accessory may alternatively be modular and/or removable with respect to the protective device. The protective device may itself, or in combination with the accessory, provide protection as rigid and/or flexible elements engage parts of the portable electronic device. An example protective device may include substantially rigid elements such as a base and one or more retention elements protruding from the base (e.g., a rim positioned about the peripheral edges of the base, a plurality of spaced apart retention elements protruding from peripheral edges of the base, etc.). Such an embodiment may define a shell into which the portable electronic device may be positioned and secured. In another embodiment, a protective device may be flexible, or may include some flexible components. A folio may, for instance, include a base with two or more sections (e.g., panels, etc.) configured to receive and secure the portable electronic device and the accessory in place. The base may be foldable so as to allow the portable electronic device to be folded over the accessory. The folio may also allow a portion of the portable electronic device to be supported by the support element of the accessory while the base remains at least partially secured to the portable electronic device.

In addition to protective systems and protective devices, mobile computing systems and methods are disclosed. A mobile computing system may include a protective system combined with a portable electronic device. Embodiments of methods of the present disclosure provide for orienting portable electronic devices in working arrangements, using portable electronic devices that have been oriented in working arrangements and protecting the displays of portable electronic devices from damage during storage or transportation. In one such method, a portable electronic device may be assembled with a protective system or a protective device in a working arrangement. The peripheral component of the accessory may be configured to communicate with the portable electronic device while the portable electronic device is in the working arrangement with the accessory. When the portable electronic device is not in the working arrangement, the portable electronic device may be placed in the protected arrangement. In the protected arrangement, a display of the portable electronic device may be at least partially covered by the accessory or a protective cover associated with the accessory.

In some embodiments, a portable electronic device may be supported by a stand which is insufficiently sturdy to allow use in a wide variety of positions or arrangements, or to maintain the position of the portable electronic device during transport or movement. In one embodiment of the present disclosure, a sturdy support device is provided that allows the portable electronic device to remain at a working arrangement while in use, while in motion, or while being transported. For instance, a protective cover and support system may include a protective cover with at least one substantially rigid portion. An accessory, such as a keyboard, may be secured to the substantially rigid portion. The accessory may include a support element that provides a sturdy support for the portable electronic device. If the system is placed, for instance, on a user's lap, the substantially rigid portion of the protective system can, along with the accessory, brace and support the portable electronic device in a working arrangement. Similarly, by grasping the substantially rigid portion, a user may move the entire system potentially without requiring removal of the portable electronic device from the support element, or without requiring the user also brace the portable electronic device.

In one embodiment, the protective cover remains connected to at least a portion of the portable electronic device while the portable electronic device is supported by the accessory in a working arrangement. By way of illustration, a first portion of a foldable protective cover may carry the accessory, while another portion of the protective cover may carry the portable electronic device. Two corner and/or side rail connections may secure the portable electronic device in a manner that also allows the portable electronic device to be removed (e.g., by sliding the portable electronic device out of the corners and/or side rails, etc.). Optionally, the corners and side rails and/or other connection devices, are secured by insubstantially overlapping a front surface, or display surface, of the portable electronic device. By way of example, the side rails and/or corners may overlap a corresponding location of the front surface of the portable electronic device (e.g., by a distance of about 1 millimeter to about 10 millimeters, etc.).

Other aspects, as well as the features and advantages of various aspects, of the disclosed subject matter will become apparent to those of ordinary skill in the art through consideration of the ensuing description, the accompanying drawings and the appended claims.

### BRIEF DESCRIPTION OF THE DRAWINGS

In order to describe the manner in which features and other aspects of the present disclosure can be obtained, a more particular description of certain subject matter will be rendered by reference to specific embodiments which are illustrated in the appended drawings. Understanding that these drawings depict only some embodiments and are not therefore to be considered to be limiting in scope, nor drawn to scale for all embodiments, various embodiments will be described and explained with additional specificity and detail through the use of the accompanying drawings in which:

FIG. 1 is a perspective view of a protective system according to an embodiment of the present disclosure, the protective system including a protective case and an accessory;

FIG. 2 is a top plan view of the protective system illustrated in FIG. 1;

FIG. 3 is a cross-sectional side view of the protective system of FIG. 1, taken along the line 3-3 of FIG. 2;

FIG. 4 is a partial cross-sectional view of the protective system of FIG. 1, the accessory of the protective system supporting a portable electronic device in an at least partially upright position relative to the protective system;

FIG. 5 is a perspective view that illustrates an embodiment of a portable electronic device oriented in an at least partially upright landscape working arrangement relative to the embodiment of the protective case illustrated by FIG. 1;

FIG. 6 is a perspective view that illustrates an embodiment of a portable electronic device oriented in an at least partially upright portrait working arrangement relative to the embodiment of the protective case illustrated in FIG. 1;

FIG. 7 is a perspective view that illustrates a protective case maintained in a protected arrangement relative to a portable electronic device;

FIG. 8 is a partial cross-sectional representation of the protective system of FIG. 7, with the protective case at least partially secured in a protected arrangement relative to the portable electronic device;

FIG. 9 is a perspective view illustrating an accessory being selectively removable from a protective case;

FIG. 10 is a perspective view that illustrates an embodiment of a portable electronic device oriented in an at least partially upright landscape working arrangement relative to another embodiment of a protective case;

FIG. 11 is a perspective view that illustrates an embodiment of a portable electronic device oriented in an at least partially upright portrait working arrangement relative to the embodiment of the protective caseillustrated in FIG. 10;

FIG. 12 is a rear perspective view that illustrates an embodiment of a portable electronic device oriented in an at least partially upright position relative to another embodiment of a protective system that includes a foldable protective cover and an accessory;

FIG. 13 is a perspective view that illustrates a protective system similar to that of FIG. 12, while in a partially closed position and including a clasp element;

FIG. 14 is a top plan view of the protective system of FIG. 12 in an unfolded, open position;

FIG. 15 is a perspective view of the protective system of FIG. 14 in an unfolded, open position, with the portable electronic device and accessory removed therefrom; and

FIG. 16 is a perspective view of a protective system similar to that of FIG. 12, illustrating a partially open position from which the portable electronic device may be removed from the protective cover.

### DETAILED DESCRIPTION

Aspects of the present disclosure generally relate to protective covers and/or accessories configured for use with portable electronic devices. By way of example and not limitation, such protective covers and/or accessories may be used with so-called “tablet” or “slate” computer, a smart phone, an e-reader or other mobile computing devices or the like. Examples of tablet computers that may be used with an accessory 100 include, but are not limited to the IPAD® available from Apple Inc., the Motorola Mobility, Inc.'s XOO™, the BLACKBERRY PLAYBOOK™ from Research in Motion Limited, the STREAK™ available from Dell Inc., and Hewlett-Packard Co.'s TOUCHPAD™, among others. An accessory 100 may be configured for use with virtually any smart phone, including, without limitation, Apple, Inc.'s IPHONE®s, the Samsung GALAXY®, and Research In Motion Limited's BLACKBERRY® phones. Among the various types of e-readers and other mobile computing devices with which an accessory 100 may be used are the IPOD TOUCH® available from Apple Inc., the KINDLE® available from Amazon Technologies, Inc., the NOOK™ available from Barnes & Noble, Inc., the DS™ available from Nintendo Co., Ltd., and the like.

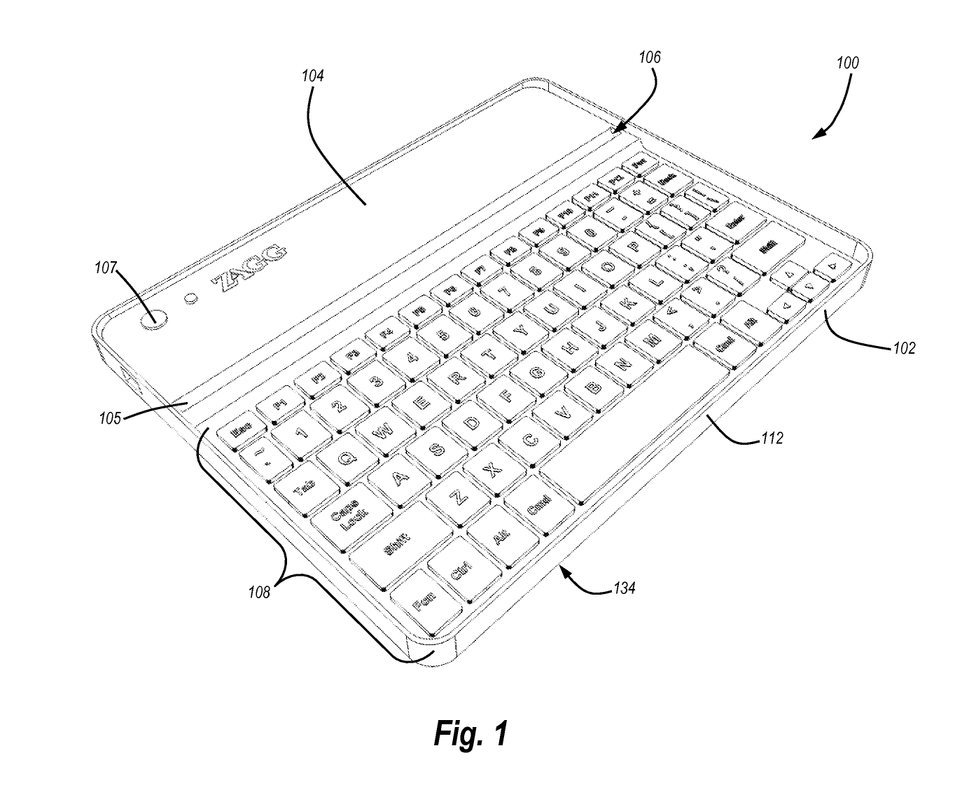

FIGS. 1-3 illustrate an embodiment of a protective system 100. As shown, a protective system 100 may include a protective device 102, in this case a protective case, and an accessory 104. The accessory 104 may include at least one support element 106.

In the illustrated embodiment, the accessory 104 is illustrated as including a keyboard 108. Such keyboard 108 may have any number of configurations. For instance, the keyboard 108 may include any number of keys 110, and the keys 110 may be arranged in any particular format, layout, pattern or other arrangement. For instance, the keyboard 108 of the illustrated embodiment arranges the alphanumeric keys in a QWERTY-style format, while also including various keys for directional input, functional controls, and the like.

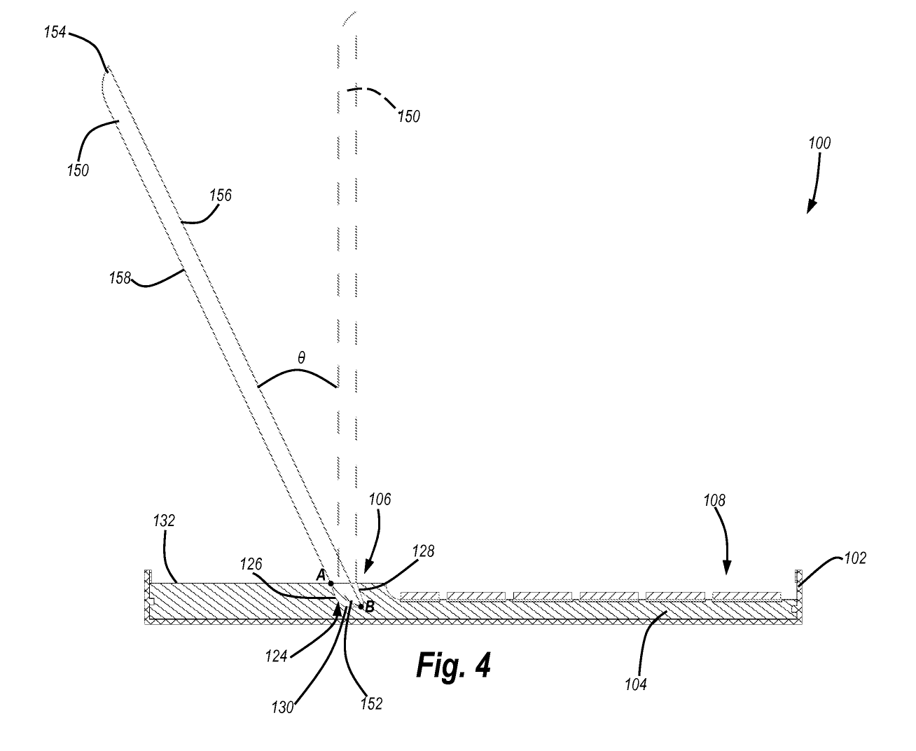

The accessory 104 may have any number of different shapes, sizes, and/or configurations. For instance, the accessory 104 may have a generally uniform thickness, width, length, or other dimension. In other embodiments, such as that illustrated in FIG. 4, one or more of the dimensions of the accessory 104 may vary. In some embodiments, for instance, the keyboard 108 is thinner than a rear portion of the accessory 104 (e.g., near surface 132 and/or support element 106). Such variation, while optional, may reduce the weight of the accessory 104, increase the depth of elongated recess 105 of the support element 106 (which may provide for greater leverage at the support element 106) or provide other functions. Increased thickness in one or more portions of the accessory 104 may, for instance, be used to accommodate other aspects such as circuitry, wireless transmitters/receivers, power sources, and the like. In other embodiments, the keyboard 108 may have the same thickness as or a greater thickness than other portions of the accessory 104.

The configurations of the protective device 102 and/or of the accessory 104 may be customized for use with a particular type of portable electronic device 150. For instance, the protective device 102, the accessory 104 and the support element 106 of the accessory 104 may be configured to operate specifically with a particular device (e.g., a tablet computing device such as an IPAD®, etc.). In such embodiments, the protective device 102, the accessory 104 and/or the support element 106 may be configured (e.g., sized, shaped, etc.) specifically to complement and/or accommodate the form factor of the particular device.

The keyboard 108 may be configured to connect to a portable electronic device or other computing device in any suitable fashion. The keyboard 108 may, by way of illustration, have wireless capabilities (e.g., infrared, BLUETOOTH®, etc.). For instance, a wireless connectivity feature 107 may be provided, as illustrated in FIG. 1. The wireless connectivity feature 107 may take the form of a button, switch, toggle, or other component, or any combination of the foregoing, and can be used to initiate or maintain a wireless connection with a computing device. By way of illustration, where the wireless connectivity feature 107 is a button, a user may depress the button which may turn on the wireless features or otherwise cause the accessory 104 to search for or connect to a corresponding wireless-capable device. In lieu of a wireless connection, the accessory 104 may use a direct or wired connection (e.g., USB, serial, etc.) that is configured to communicatively couple the keyboard 108 to a corresponding portable electronic device. Of course, the keyboard 108 and accessory 104 may include other or additional capabilities.

While the accessory 104 is illustrated as including a keyboard 108, the accessory 104 may include or have the form of any number of additional or other devices or features. For instance, other accessories that may be used in connection with embodiments of the present disclosure may include any combination of: batteries or other power sources configured to provide primary or backup power for a computing device; audio devices (e.g., speakers, microphones, portable musical keyboards, turntables, mixers, etc.); printers; scanners; peripheral storage or memory devices (e.g., disk drives, hard drives, solid state storage devices, etc.); communication elements configured to provide a computing device with alternate and/or additional means of communication (e.g., USB or USB micro ports, HDMI ports, FireWire interfaces, i.LINK interfaces, Lynx interfaces, 8P8C jacks, etc.); or other devices or accessories, or any combination of the foregoing. In some embodiments, various peripheral components may have a modular nature so as be interchangeable with a housing of the accessory 104.

As shown in FIGS. 1-3, the accessory 104 may in some embodiments be positioned within or otherwise associated with the protective device 102. The protective device 102 may protect the accessory 104 from damage, wear, or the like. In some embodiments, the protective device 102 may also act as a cover or enclosure for all or a portion of a portable electronic device (not shown). The protective device 102 may protect the portable electronic device when such device is in use and/or when in a protected arrangement. In at least some embodiments of the present disclosure, the protective device 102 includes a retention element 134. The retention element 134 may be configured to engage part (e.g., a peripheral edge, a feature, etc.) of the accessory 104 and to secure the accessory 104 to the protective device 102.

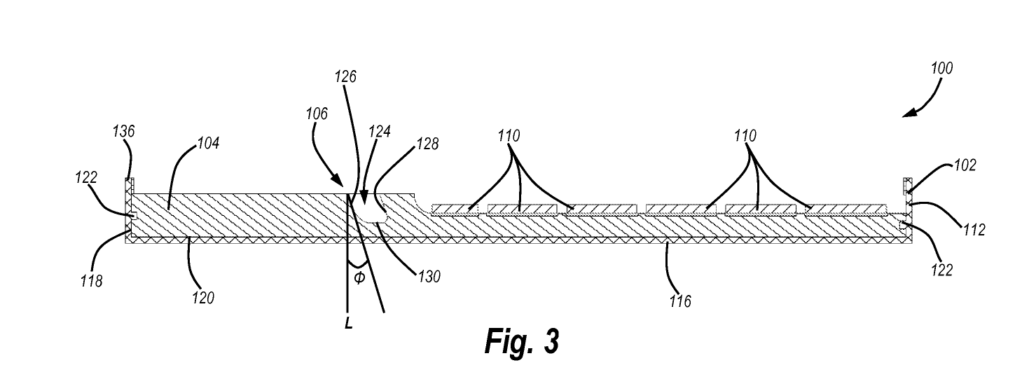

As best illustrated by FIG. 3, the at least one retention element 134 may include one or more peripheral elements 136 that protrude substantially perpendicular from an outer periphery of a base 116 of the protective device 102. The peripheral element(s) 136 may include features such as side walls, discrete or spaced apart members (e.g., tabs, etc.) and the like, or any combination of features that may engage the outer periphery of a portable electronic device. The base 116 and peripheral elements 136 may collectively define a receptacle within which the accessory 104 may be positioned. Thus, the shape and dimensions of the protective device 102 may be configured to enable the receptacle to receive the accessory 104. In such an embodiment, an interior surface 114 of each peripheral element 136 may engage or otherwise be located adjacent to a corresponding outer peripheral edge 118 of the accessory 104. Similarly, the base 116 may be configured to engage or be positioned proximate the base surface 120 of the accessory 104.

In at least some embodiments, the sizes, shapes, configurations, topography, or other features of the interior surface 114 of each peripheral element 136 and the outer peripheral edge 118 of the accessory 104, and of the base 116 and base surface 120 of the accessory 104 may be substantially the same or may otherwise be generally complementary. For instance, where one or more dimensions of the interior surface 114 and the outer peripheral edge 118 are about the same, the accessory 104 may engage or otherwise be positioned or secured against the interior surface 114 of each peripheral element 136 using a frictional or interference fit. The accessory 104 may also be supported within a chamber at least partially defined by the base 116 and the retention element 134 by positioning the base surface 120 of the accessory 104 against or adjacent the base 116 of the protective device 102. The accessory 104 may thus be protected or otherwise maintained in a particular position or orientation relative to the protective device 102.

In some embodiments, one or more retaining structures 122 may be utilized to secure the accessory 104 to the protective device 102. For instance, in the embodiment illustrated in FIG. 3, each retaining structure 122 may comprise a detent that corresponds to a groove or other indentation in the accessory 104. Such an indentation or other structure may be temporary or permanent. For instance, the accessory 104 may be at least partially flexible such that a groove is temporarily formed when a rigid or other structure of the protective device 102 deforms the outer peripheral edge 118 of the accessory 104 to create an interference fit. It will be appreciated that in embodiments in which one or more retaining structures 122 are included, such retaining structures 122 may take any suitable form, and can be included with the protective device 102 and/or the accessory 104. Other suitable retaining structures 122 may include snap-fits, catches, latches, or other elements, or any combination of the foregoing.

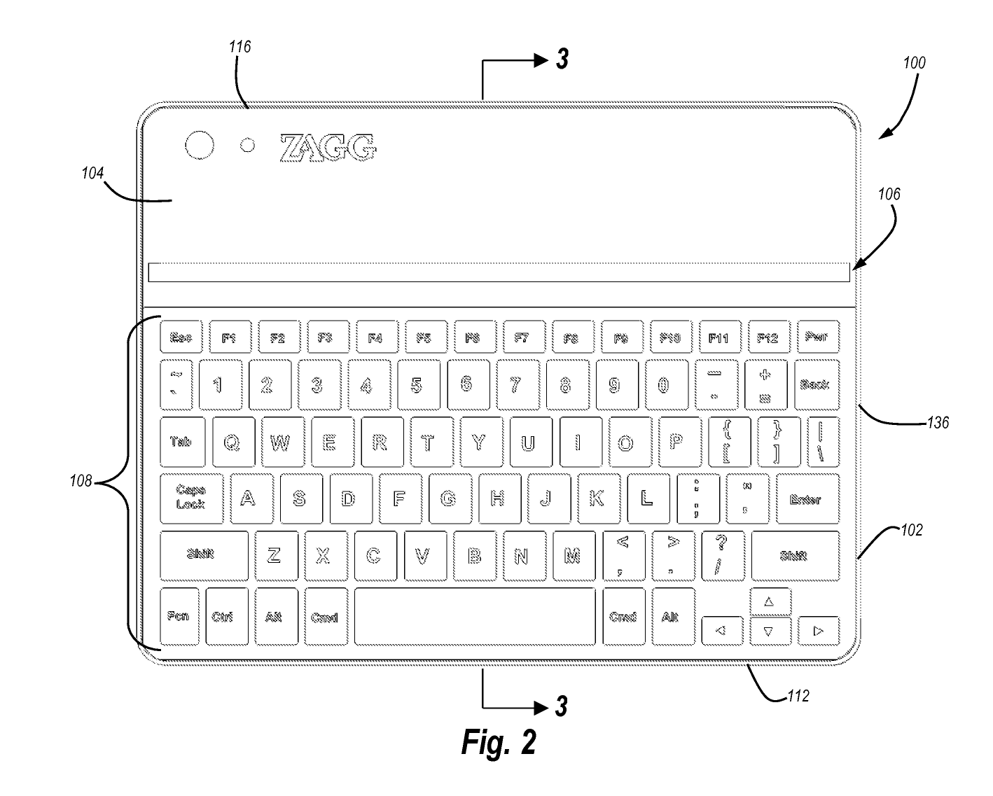

With continued reference to FIGS. 1-3, a shell 112 may optionally be formed by one or more components of the protective device 102. For instance, in the illustrated embodiment, the shell 112 may be formed by the peripheral elements 136 which extend around all or a portion of the base 116 of the protective device 102. The accessory 104 of FIGS. 1-2 may have a generally rectangular shape, and the shell 112 can, in accordance with some embodiments, have a generally corresponding shape (e.g., a rim, etc.) that forms a perimeter around all or a portion of the accessory 104.

As shown in FIG. 3, the shell 112 may be formed using the one or more peripheral elements 136 such that the interior surface 114 of each peripheral element 136 extends at an angle that is about perpendicular relative to the base 116. Such orientation is, however, merely one example of a suitable orientation. In other embodiments, the peripheral elements 136 and/or the interior surface 114 may be oriented at acute or obtuse angles relative to the base 116. Furthermore, while the interior surface 114 may be generally fixed at a particular angle relative to the base 116, in other embodiments, all or a portion of the interior surface 114 and/or the peripheral elements 136 may be configured to pivot, hinge, flex, or otherwise change relative to the base 116.

The retention element 134, including the optional shell 112, may extend around all or a portion of the base 116. For instance, in some embodiments, the peripheral elements 136 and the shell 112 and can extend substantially uninterrupted along the entire perimeter of the base 116 and/or the accessory 104. In other embodiments, the peripheral elements 136 and/or the shell 112 may be interrupted or segmented. By way of example, the peripheral elements 136 may have one or more slots, openings, depressions, or other features, or any combination of the foregoing formed or otherwise provided therein. Such features may, for instance, correspond to expected locations of ports, buttons, or other elements of the accessory 104 or a portable electronic device (not shown). Additionally, or alternatively, the peripheral elements 136 and/or the shell 112 may be segmented into multiple, discrete walls or portions that collectively make up all or a portion of the shell 112 and/or the retention element 134. Furthermore, while the peripheral element 136 is illustrated as having a generally constant height, such an embodiment is merely one example embodiment, and the height of the one or more peripheral elements 136 may vary as desired to satisfy a desired functional, ornamental, or other purpose.

With continued reference to FIGS. 1-3, it will be appreciated that the protective system 100 may include a support element 106 configured to be used in connection with a portable electronic device. The support element 106 may be configured for use with a particular type of portable electronic device 150 (or portable electronic devices 150 having a specific configuration and/or dimension(s)) or with portable electronic devices 150 having a variety of different configurations and dimensions.

The support element 106 may be configured to orient a portable electronic device 150 in a working arrangement, such as an inclined orientation, or an at least partially upright orientation, relative to the accessory 104 (i.e., when a base of the housing is placed on a horizontal or substantially horizontal support surface). The support element 106 may be positioned at a location relative to the remainder of the accessory 104 that enables the accessory 104 to stably support a portable electronic device 150 as the portable electronic device 150 is held in an inclined orientation. As shown, the support element 106 may be located off-center of a depth of the accessory 104, but well in front of a rear edge of the accessory 104, leaving a sufficient portion of the accessory 104 to counter the effects of gravity on a portable electronic device 150 supported in an inclined orientation by the support element 106 and the remainder of the accessory 104. Optionally, the accessory 104 may be weighted in a manner that further counteracts any tendency of an inclined portable electronic device 150 to top the accessory 104.

The support element 106 may include an elongated recess 105, which may extend at least partially across a width of the accessory 104. More particularly, the elongated recess 105 may comprise a groove or a channel 124 in an upper surface 132 of the accessory 104. The groove or channel 124 may be defined by various surfaces of the accessory 104. In the illustrated embodiment, a base surface 130, which is recessed relative to an upper surface 132 of the accessory 104 and which may be oriented generally parallel to a top surface and/or base surface 120 of the accessory 104, defines a lower extent of the groove or channel 124. The groove or channel 124 may also include front and rear surfaces 128 and 126, respectively, which may be oriented transverse to the base surface 130. A width of the groove or channel 124 (e.g., a distance between the front surface 128 and the rear surface 126, etc.) may accommodate the width of a portion of a portable electronic device 150 to be inserted therein.

In at least one embodiment, the groove or channel 124 is open at the top surface 128 of the accessory 104. Of course, a depth of the groove or channel 124 may be less than a thickness of the accessory 104. Accordingly, the base surface 130 of the groove or channel 124 may be at least partially offset from the base surface 130 of the accessory 104. In various embodiments, the groove or channel 124 may extend only slightly into the accessory 104, or it may extend substantially through the accessory 104. For instance, the groove or channel 124 may extend through the accessory 104 to its base surface 120 (e.g., the upper surface of a substantially planar element that forms the base surface 120 of the accessory 104, etc.).

In other embodiments, a groove or channel 124 may extend completely through the accessory 104 and, thus, lack a base surface 130.

In a specific embodiment, the groove or channel 124 may have a depth of about one-eighth inch (about 3.17 mm) to about three-quarters inch (about 19.05 mm) deep, and has a width that is approximately one-hundred percent to about two-hundred percent of the width of a portable electronic device 150 that may be supported by the support element 106 and the remainder of the accessory 104. The width of the groove or channel 124 at its base surface 130 may be about one-quarter inch (about 6.35 mm) to about three-quarters inch (about 19.05 mm). The groove or channel 124 may be sized and configured to enable a portable electronic device 150 to be inclined and to create a leverage to selectively and removably secure the portable electronic device 150 in place relative to the accessory 104.

In some embodiments, a relatively wide groove or channel 124 may be configured to receive one or more inserts to accommodate relatively thin portions of portable electronic devices 150. Such an insert may effectively decrease the width of the groove or channel 124 and, in some embodiments, effectively change the angle at which the groove or channel 124 orients a portable electronic device 150.

In addition to including a groove or channel 124 with front and rear surfaces 128 and 126, respectively, a support element 106 of an accessory 104 may include other features (e.g., lips, ridges, grooves, other wall features (e.g., curvatures, undulations, other non-planar configurations, etc.), coatings, etc.) that may at least partially support and/or engage a edge portion of a portable electronic device 150. As a non-limiting example, a lip or overhang may from a front of the groove or channel 124 (e.g., from the front surface 128, from a location laterally adjacent to the front surface 128, from a location above the front surface 128, etc.), over a portion of the groove or channel 124.

The support element 106 may, in accordance with some embodiments of the present disclosure, be configured to support a portable electronic device 150 at an inclined angle relative to the accessory 104. For instance, the rear surface 126 of the groove or channel 124 may be oriented at an obtuse angle. More particularly, the rear surface 126 may be oriented at an angle φ relative to a line L. The line L of the illustrated embodiment is about normal to the base surface 120 of the accessory 104, and to the base surface 130 of the support element 106, although the angle φ may be defined with respect to any particular line or plane. Regardless of the manner in which the angle φ is defined, the degree of the angle φ may vary as desired. For instance, in some embodiments, the angle φ may be about zero and the rear surface 126 and/or the groove or channel 124 may be about perpendicular to the base surface 120 of the accessory 104 and/or the base 130 of the groove or channel 124 of the support element 106. In other embodiments, the angle φ may be larger than zero. By way of illustration and not by way of limitation, the angle φ may be greater than zero degrees up to about sixty degrees.

The cross-sectional shape of the groove or channel 124 may vary based on the relative orientations of its surfaces 130, 126 and 128. Indeed, in some embodiments, the shape of the groove or channel 124 optionally varies along a length of the groove or channel 124. For instance, at one or more locations, the cross-sectional shape of the groove or channel 124 may be defined by the base surface 130, the rear surface 126, and the front surface 128.

The front surface(s) 128 of the groove or channel 124 may optionally be oriented at an angle relative to the line L, the base surface 130 of the groove or channel 124, the base surface 120 of the accessory 104 or some other reference line or plane. In some embodiments, for instance, the front surface 128 may be oriented parallel or substantially parallel to the rear surface 126 of the groove or channel 124. In such an embodiment, the groove or channel 124 may have a somewhat parallelogram-shaped cross-section. Alternatively, a cross-sectional shape of the groove or channel 124 may be generally trapezoidal. For instance, the rear surface 126 and the front surface 128 may be oriented non-parallel to one another, while the base surface 130 of the groove or channel 124 and the top surface 128 of the accessory 104 may be parallel or substantially parallel to one another.

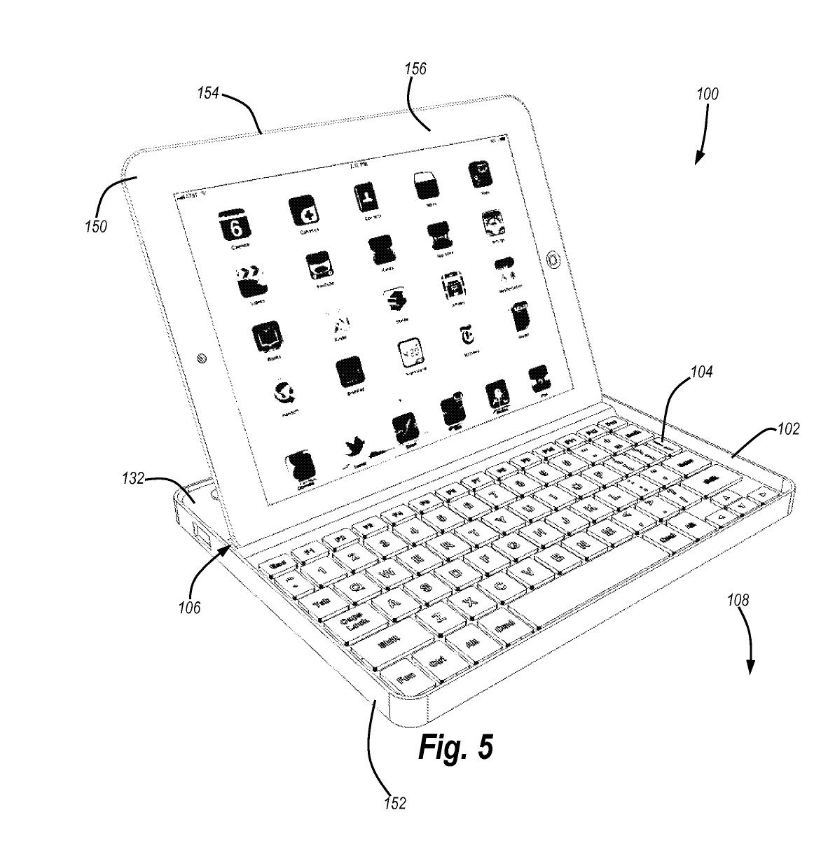

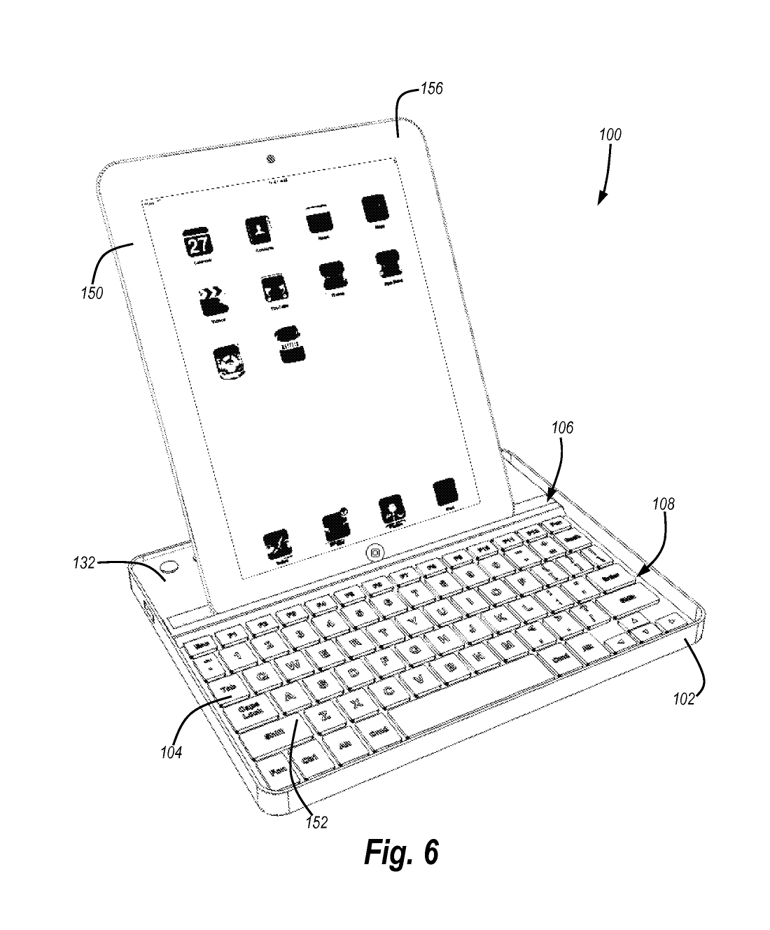

FIGS. 4-6 illustrate embodiments in which a support element 106 of an accessory 104 holds a portable electronic device 150 in an upright, working arrangement. In some embodiments, the portable electronic device 150 may be positioned in a landscape orientation (see FIGS. 4 and 5) and/or in a portrait orientation (see FIG. 6).

As best illustrated in FIG. 4, support element 106 may support an electronic device 150 in an at least partially upright position. An edge portion 152 of the electronic device 150 may be assembled with the support element 106, such as by inserting the edge portion 152 into a groove or channel 124 of the support element 106. Once the edge portion 152 of the electronic device 150 has been inserted into the groove or channel 124, the electronic device 150 may be rotated about the edge portion through the angle θ (e.g., an opposite edge of the electronic device 150 may be moved toward a rear of the accessory 104, etc.) to the illustrated inclined orientation. As indicated previously herein, the groove or channel 124 may be configured to orient the electronic device 150 at one or more inclined angles relative to the accessory 104. For instance, the rear surface 126 and/or the front surface 128 of the groove or channel 124 and/or any other feature associated with the groove or channel 124 may be configured (e.g., oriented at an angle, etc.) to orient the electronic device 150 at a desired angle (e.g., a non-parallel and non-perpendicular angle, a perpendicular angle, etc.) to one or both of the base surface 130 of the groove or channel 124 and the base surface 130 of the accessory 104. The phantom lines in FIG. 4 depict an embodiment where the electronic device 150 may be supported perpendicularly relative to the accessory 104. In other embodiments, the electronic device 150 may oriented at a non-perpendicular angle. In FIG. 5A, the angle θ defines an angle at which the electronic device 150 is offset from a vertical, upright, or other orientation. The angle θ may measure an angle between the electronic device 150 and a line that is about normal relative to a cross-sectional length of the accessory 104. The magnitude of the angle θ may vary as desired. For instance, and without limitation, the angle θ varies between about zero and about sixty degrees.

In such an orientation, leverage or some other mechanical advantage may limit further rotation of the electronic device 150 and, in some embodiments, at least partially secure the edge portion 152 of the electronic device 150 in the groove or channel 124. More particularly, to create such leverage, the accessory 104 may be configured to provide two or more offset contacts. In the embodiment in FIG. 5A, such contacts may correspond to locations along both a front surface 156 and rear surface 158 of the portable electronic device 150. For instance, the rear surface 158 may contact the angled rear surface 126 of the groove or channel 124. Such contact may occur at a point, at one or more points, or substantially continually along a contact axis or surface extending laterally along all or a portion of the width (i.e., into the page) of the accessory 104. The contact is represented by reference A and is, in this embodiment, located at or near a junction between an upper surface 132 of the accessory 104 and the rear surface 126 of the groove or channel 124. A second contact may be present and in this embodiment is represented by reference B. Contact B may exist at one or more points, along an axis or plane, or in another manner, and can be located at the front surface 128 of the groove or channel 124. More particularly, in the illustrated embodiment, contact B may be at a location at or near a junction between the base surface 130 and the front surface 128 of the groove or channel 124. Contact B may, of course, be longitudinally offset (relative to a height, or thickness, of the accessory 104) from the upper surface 132 of the accessory 104 and located at or near the base surface 130 of the groove or channel 124. Contact B is optionally nearer the keyboard 104 than contact A, although such an embodiment is not limiting. Accordingly, in some embodiments, contacts A and B may be offset in at least two directions (e.g., horizontally and vertically in the orientation shown in FIG. 5A). Additionally, while only two contacts are specifically described, the electronic device 150 may engage the support element 106 at more than two points, along more than two axes, along one or more planar or other surfaces, or in any number of other manners that enable the accessory 104 and the support element 106 to support the electronic device 150 in an inclined orientation, or working arrangement.

As is already apparent from the foregoing, the groove or channel 124 or another feature any embodiment of support element 106 may create sufficient leverage to support the electronic device 150 in an inclined orientation. The leverage created by the support element 106 may be sufficient to support the electronic device 150 in the absence of support from additional or supplemental apparatuses. For instance, the support element 106 may create enough leverage at the edge portion 152 of the electronic device 150 to maintain the electronic device 150 in the illustrated working arrangement even absent utilization of a stand or an external (to the accessory 104) support (e.g., a counterweight, etc.).

The accessory 104 may be weighted or otherwise configured to maintain the portable electronic device 150 in an upright position without tipping. For instance, at the distal end 154 of the portable electronic device 150, a gravitational force may create a moment relative to the proximal end 152, which moment may tend to cause the system 100 to tip in a rearward, counter-clockwise direction. To counter such a tendency, the accessory 104 may be weighted in a suitable manner. Such weighting or other configuration may allow, for instance, the protective system 100 to be self-supported such that the portable electronic device 150 is maintained upright while positioned in a landscape orientation as shown in FIG. 5, in a portrait orientation as shown in FIG. 6, or in some other orientation. By way of illustration, the accessory 104 may have sufficient mass to overcome such a moment, or may be selectively weighted to place the center of gravity of the accessory 104 at a desirable location. For instance, the center of gravity may be positioned near the forward side of the keyboard 108.

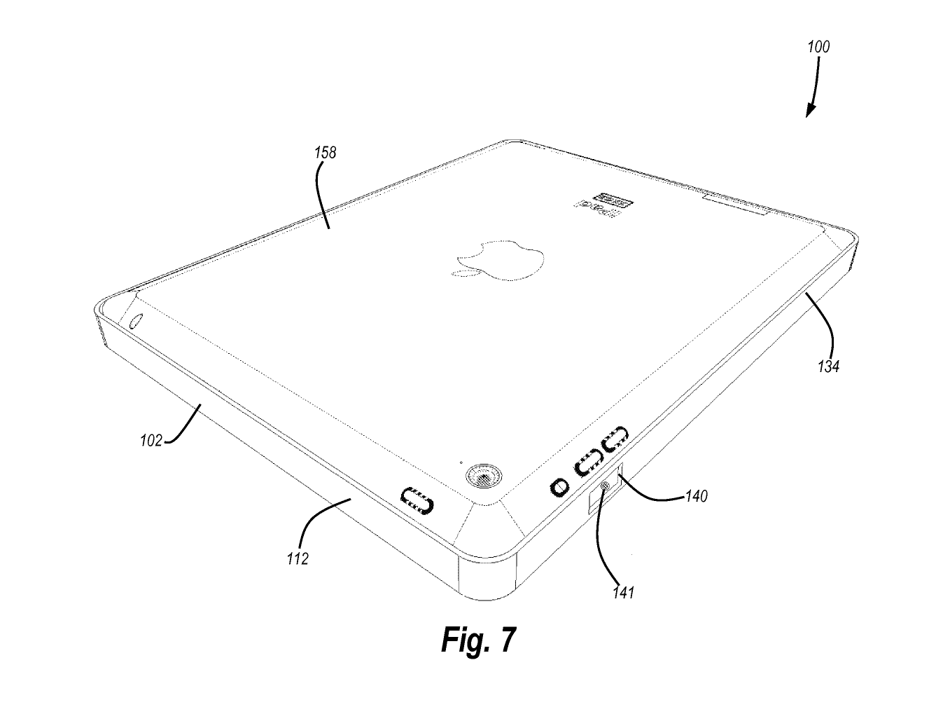

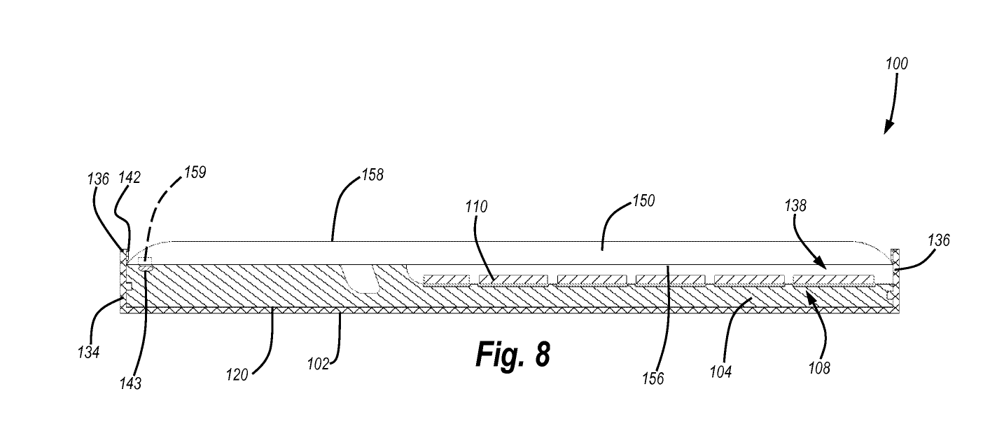

The portable electronic device 150 may be used and maintained at any number of predetermined orientations or positions relative to the accessory 104 and/or the protective device 102. For instance, as noted herein, FIG. 5 illustrates a first state in which the portable electronic device 150 is maintained in an upright, landscape orientation relative to the accessory 104, while FIG. 6 illustrates a second state in which the portable electronic device 150 is maintained in an upright, portrait orientation relative to the accessory 104. The portable electronic device 150 may also be maintained at any number of additional or alternative orientations. Referring now to FIGS. 7 and 8, another orientation of the portable electronic device 150 is described in additional detail. In particular, the illustrated embodiment depicts the portable electronic device 150 in a protected arrangement.

The portable electronic device 150 may include a display 151 (FIG. 5) which may provide graphical, textual, or other output to a user, and which optionally includes touch-screen or other similar input technology. Great care is often taken to protect such a display 151 from damage, as any damage will affect the appearance of the display 151 and may reduce its input and/or output functionality. In the embodiments shown in FIGS. 4-6, the display 151 may generally be positioned at the front surface 156 of the portable electronic device 150 so as to be oriented towards the keyboard 108 while the portable electronic device 150 is in an upright working arrangement relative to the accessory 104. In contrast, and as best illustrated by FIGS. 7 and 8, when the portable electronic device 150 is in the protected arrangement, the front surface 156 and the display 151 may covered by the accessory 104 and/or a portion of the base 116 of the protective device 102 and, thus, be hidden from view and substantially prevented from external contact, and thus protected from the environment or other potentially damaging conditions.

More specifically, the base 116 of the protective device 102 and/or the accessory 104 may be configured to be positioned over and to completely cover or substantially cover (e.g., in embodiments that include perforations, slots, etc.) the display 151 of the portable electronic device 150. The base 116 of the protective device 102 includes an interior surface, which in the illustrated embodiment, may be configured to be placed adjacent to or against the base surface 120 of the accessory 104. The accessory 104 may, in turn, also have an upper surface 132, keys 110, or other surfaces or elements that may be configured to be placed adjacent to or against the display 151 of the portable electronic device 150.

The protective device 102 may be configured to securely retain the portable electronic device 150 in the protected arrangement. In accordance with at least one embodiment, the at least one retention element 134 of the protective device 102 may be configured to secure the portable electronic device 150 and, optionally, the accessory 104 to the protective device 102. For instance, the at least one retention element 134 may be configured to engage part (e.g., a peripheral edge, a feature, etc.) of the portable electronic device 150 and to secure the portable electronic device 150 to the protective device 102. As discussed herein, the at least one retention element 134 may comprise one or more protruding peripheral elements 136. In such an embodiment, the peripheral elements 136 protrude from the base 116 at a location at or adjacent to an outer peripheral edge thereof. The peripheral elements 136, whether comprising continuous or non-continuous rims, a plurality of discrete, spaced apart members (e.g., tabs, etc.) or other structures, may be configured to be positioned adjacent to opposite, outer peripheral edges of the portable electronic device 150. The base 116 and the peripheral elements 136 may define a receptacle 138. In some embodiments, the receptacle 138 may accommodate the accessory 104 and at least a portion of the thickness of the portable electronic device 150. In such an embodiment, the upper surface 132 of the accessory 104 may be recessed within the receptacle 138 a sufficient depth that the receptacle 138 may also accommodate at least a portion of the thickness of the portable electronic device 150 in a display side-down orientation, thereby enabling the display 151 of the portable electronic device 150 to be positioned adjacent to or against the accessory 104, such that the display 151 and portable electronic device 150 are protected by the base 116 of the protective device 102, the accessory 104 and the peripheral elements 136 of the protective device 102.

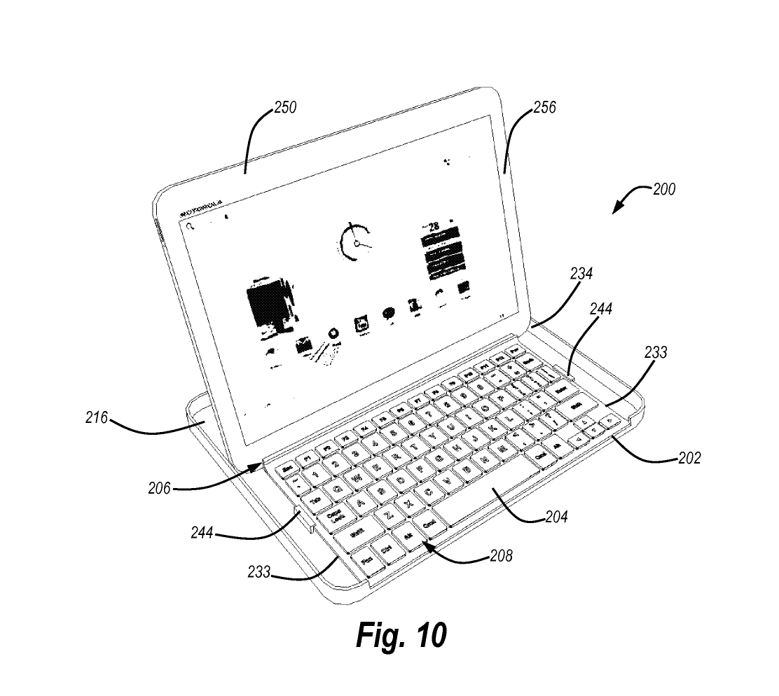

In some embodiments, the at least one retention element 134 may comprise a single peripheral element 136 (i.e., a rim, etc.) that is configured to extend continuously and completely around the periphery of the portable electronic device 150 when the portable electronic device 150 is introduced, display side-down, into the receptacle 138 of the protective device 102. In other embodiments, the peripheral element 136 may include multiple, discrete segments or pieces. The height(s) of the peripheral element(s) 136 may be constant or they may vary around the periphery of the protective device 102. For instance, the height(s) of the peripheral element(s) 136 may vary to accommodate ports or other features of the portable electronic device 150 and/or of the accessory 104. In some embodiments, a height of the one or more peripheral elements 136 may be reduced at or near a location wherein an individual may access the keyboard 108. Such a recess may have an elevation that is about the same as, or below, an elevation of the upper surface of the keyboard 108 (see FIG. 10). Such reduced height may, for instance, allow for improved access to the keyboard 108.

The at least one retention element 134 and/or the base 116 of a protective system 100 that incorporates teachings of the present disclosure may further be configured to accommodate physical connections between the portable electronic device 150 or the accessory 104, and one or more external devices or elements while the portable electronic device 150 is positioned within the receptacle 138 of the protective device 102 or in an upright working arrangement, as discussed herein. In this regard, in the embodiment depicted by FIG. 7, an access feature 140 may be provided through a peripheral element 134 or the base 116 of the protective device 102. While the access feature 140 is illustrated as comprising a rectangular opening within the peripheral element 134 or the base 116, other configurations of access features 140 are also within the scope of the present disclosure. For instance, access features 140 may have any suitable geometric or other shape and/or may take the form of slots, holes, openings, removable panels, depressions, or other features, or any combination of the foregoing.

The access feature 140 may correspond to a communication port, a button, a switch or any other feature of (e.g., on or adjacent to an outer periphery of, on or adjacent to a back side of, etc.) the accessory 104 or to a communication port, an audio jack, a speaker, a microphone, a camera, a button, a switch or any other feature of (e.g., on or adjacent to an outer periphery of, on or adjacent to a back side of, etc.) the portable electronic device 150. For instance, the access feature 140 may correspond to the location of a communication port that is used to facilitate communication between one or more devices that are external to the protective device 102 and one or more accessories 104 of the protective device 102 and, optionally, directly or indirectly (e.g., through an accessory 104, etc.) with the portable electronic device 150 that has been assembled with the protective device 102. Each communication or other port may be accessible through a corresponding access feature 140 in a peripheral element 136 or base 116 of the protective device 102, and may be associated with the accessory 104 in a suitable manner. In embodiments where the accessory 104 of the protective device 102 requires power, at least one access feature 140 may correspond to a power input of any suitable type known in the art (e.g., a USB port, a micro USB port, a jack for a DC power converter, etc.), and may be associated with the accessory 104 in a manner that enables power to be provided directly or indirectly (e.g., through one or more batteries, etc.) to the accessory 104 or the electronic device 150. Similar access features 140 may be provided for any number of other or additional features. Example features may include: storage device connections (e.g., connections to external drives, USB connections to solid-state storage devices, etc.); video or audio output or input devices (e.g., speakers, microphones, HDMI ports, still or video camera, etc.); connections between the accessory 104 and the portable electronic device 150 (e.g., antennas, wire connectors, etc.); or other accessories (e.g., SIM, SD, micro SD, or other card reader slots, etc.). Without limiting the scope of the present disclosure, the protective device 102 may thus include access features 140 to correspond to any number of features or elements of the accessory 104 and/or the portable electronic device 150.

In accordance with embodiments of a protective system 100 that incorporates teachings of the present disclosure, the base 116 and/or the one or more retention elements 134 of the protective device 102 may be formed from rigid or substantially rigid materials which resist deformation when localized forces are applied thereto. In addition, the at least one retention element 134 may be rigidly associated with the base 116. In such an embodiment, the base 116 and the retention element 134 may impart the protective device 102 with desired structural integrity. Examples of rigid or substantially rigid materials that may provide these characteristics include, but are not limited to, certain metals (e.g., aluminum, stainless steel, titanium, etc.), some polymers (e.g., various thermoset polymers, thermoplastic polymers, etc.), some composite materials (e.g., glass composites, carbon fiber, etc.), organic materials (e.g., wood), or other materials, or combinations of the foregoing (e.g., fiber-reinforced plastics, etc.). As shown in the depicted embodiment, the base 116 and retention element 134 of the protective device 102 may collectively form the shell 112 of the protective device 102, which may, in some embodiments, be unitary in structure.

In addition to the shell 112, a protective device 102 of the present disclosure may include an interior liner 142. A liner 142 may serve one or a variety of purposes. For example, the liner 142 may be formed from a material that cushions surfaces of the portable electronic device 150. As another example, the material from which the liner 142 is formed may enable engagement of one or more features of a portable electronic device by the retention element 134 of the protective device 102. The liner 142 may extend along all or a portion of the periphery of the shell 112, such as by being affixed to the interior surface 114 of the one or more peripheral elements 136. The liner 142 may be formed and located so as to allow the liner 142 to absorb any shock generated by impact on the shell 112, or to facilitate a frictional fit between the protective device 102 and the portable electronic device 150 and/or between the accessory 104 and the protective device 102.

Indeed, in one embodiment, the liner 142 may be used to selectively and/or temporarily secure both the portable electronic device 150 and the accessory 104 to the protective device 102 using an interference, frictional, or other type of fit. In such an embodiment, the liner 142 may comprise a compressible, resilient material. When used in conjunction with a rigid or substantially rigid retention element 134 that is rigidly associated with the base 116 of the protective device 102, the liner 142 may engage at least a portion of an outer periphery of the portable electronic device 150 and/or of an accessory 104 when placed within the receptacle 138 of the protective device 102. With sufficient force on the portable electronic device 150 and/or the accessory 104, the holding force of the liner 142 may be overcome so as to allow one or both of the portable electronic device 150 or accessory 104 to be removed from the protective device 102. Where both the portable electronic device 150 and accessory 104 are removable, both may be removed collectively, or independently relative to each other.

A variety of materials possess desirable characteristics for the liner 142. These materials include, but are not limited to, ethylene-vinyl acetate (EVA) foam (which is commonly referred to as “foam rubber” and as “expanded rubber”), polyurethane foam (e.g., microcellular polyurethane foam; fine-celled, low compression-set, high density polyurethane foam; etc.), neoprene and a variety of other compressible, resilient materials. In some embodiments, the accessory 104 may also have a liner of a same or different material or other similar material on all or a portion of the upper surface 132. Such a material may contact the display 151 on the front surface 156 of the portable electronic device 150 and absorb shock generated by impact on the base 116, on other portions of the protective device 102 or on the portable electronic device 150.

Embodiments of the protective device 102 may be configured to protect the portable electronic device 150 from damage that may otherwise occur. For instance, the protective device 102 may provide a measure of protection in the event the portable electronic device 150 is dropped, during transportation of the portable electronic device 150, and in other circumstances. Optionally, the protective device 102 may be configured to receive and cover a portable electronic device 150 without significantly adding to the dimensions of the portable electronic device 150. Without limiting the scope of the present disclosure, in some embodiments, when a protective device 102 is assembled with the portable electronic device 150 in a protected arrangement, the protective device 102 may increase a thickness of the portable electronic device 150 by no more than about three-eighths of an inch (about 9.52 mm). Likewise, a protective device 102 of the present disclosure may only add less than about one quarter of an inch (about 6.35 mm) to each of the height and width of the portable electronic device 150. Such dimensions are, however, merely examples of some suitable dimensions, and are not necessarily limiting. For instance, in other embodiments, a protective device 102 according to the present disclosure may add less than about one quarter of an inch (about 6.35 mm) or less than about eighth of an inch (about 3.18 mm) to the thickness of the portable electronic device 150 and less than about two-tenths of an inch (about 5.08 mm) to the height and width of the portable electronic device 150.

When the portable electronic device 150 is assembled with the protective device 102 in a protected arrangement, such as that illustrated by FIGS. 7 and 8, the portable electronic device 150 may be temporarily disabled. The portable electronic device 150 may, for instance, have a sleep mode or powered-down mode that can be activated when the portable electronic device 150 is not in use. Such a mode may be activated manually or automatically. For instance, in accordance with some embodiments, the portable electronic device 150 may include a sensor 159. The sensor 159 may operate magnetically, electrically, by inductance, mechanically, or by any other suitable principle. In one embodiment, the sensor 159 can detect when the portable electronic device 150 and the protective device 102 and/or accessory 104 are in the protected arrangement. By way of illustration, a corresponding feature 143 (e.g., a magnet, etc.) may be positioned within the protective device 102 or the accessory 104. When the sensor 159 is located adjacent to the feature 143, the sensor 159 may automatically trigger a sleep mode or other status of the portable electronic device 150. In some embodiments, when the sensor 159 is moved away from the feature 143, the sleep mode or other status of the portable electronic device 150 can automatically change, or be deactivated (e.g., to “wake” the portable electronic device 150 from the sleep mode, etc.). Such a feature 143 may be positioned at a location that corresponds to the location of the sensor 159 when the portable electronic device 150 is assembled with the protective device 102 and the portable electronic device 150 and the protective device 102 are in the protected arrangement.

Although the embodiment shown in FIGS. 7 and 8 may generally correspond to a state of the portable electronic device 150 when its display 151 is not in use, in other embodiments, the portable electronic device 150 may remain in use when in the protected arrangement with the protective device 102. For instance, the portable electronic device 150 may be used to provide music or other audio output while in the protected arrangement. Accordingly, it may be desirable that such audio output continue even while the portable electronic device 150 is in the protected arrangement, with its display side down.

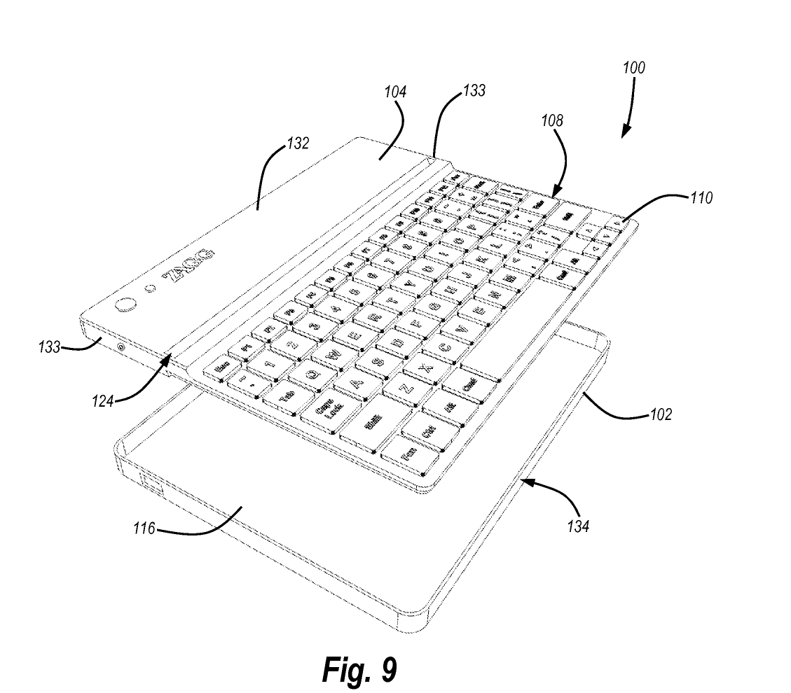

FIG. 9 depicts an embodiment in which the accessory 104 may be removably assembled with a retention element 134 of the protective device 102. In some embodiments, the accessory 104 may comprise a modular element, which may be configured for use with a plurality of different components, including a variety of different protective devices, or as a standalone accessory to a portable electronic device 150. FIG. 9 also represents a kit that may include the protective device 102 and the accessory 104, although such a kit may also include a portable electronic device 150 (FIG. 5) or other components described herein.

Separating the accessory 104 from the protective device 102 can allow any number of different arrangements between the accessory 104 and the protective device 102, and between a portable electronic device 150 and one or both of the accessory 104 and the protective device 102 to be accomplished. For instance, a consumer may want to use the accessory 104 with more than one electronic device. The accessory 104 is not limited to use with a specific device (e.g, an electronic device that may be assembled with the protective device 102, an electronic device that may be supported with the support element 106 of the accessory 104, etc.). Indeed, the accessory 104 may be used with a variety portable or non-portable electronic devices (e.g., another mobile computing device, a laptop computer, a desktop computer, etc.). To enable such use, the user may leave the accessory 104 assembled with the protective device 102. Alternatively, the user may remove the accessory 104 from the protective device 102.

The accessory 104 may also be removed from the protective device 102 for any number of other reasons. For instance, a user may have multiple protective devices that may differ in ornamentation, configuration, or in other aspects. Where the accessory 104 is removable or otherwise modular in nature, the user may be able to use the same accessory 104 in connection with any protective device that may suit the user's then current needs or whims, and without the need to purchase or obtain a separate accessory 104 for each protective device, which could be cost prohibitive in some circumstances. A user may also wish to separate the accessory 104 from the protective device 102 for other reasons. Without limiting the scope of the present disclosure, the user may further have different accessories that satisfy differing purposes that may be assembled with the protective device 102 in place of one another. One accessory may include a keyboard such as that shown in FIG. 9. Other accessories may include other peripheral components, as disclosed previously herein. Further still, in some embodiments, removal of the accessory 104 may facilitate the accomplishment of other goals (e.g., replacement of batteries, upgrading memory or storage, repair, etc.).

In embodiments in which the accessory 104 is removable, any suitable manner or mechanism for removing the accessory 104 may be utilized. By way of illustration, the shape and size of the accessory 104 may generally correspond to the shape and size of the protective device 102. Such connection may utilize a frictional, interference, or other fit or connection created when the accessory 104 is placed within the protective device 102. The accessory 104 and/or the protective device 102 may be at least temporarily deformable when a force is applied so as to allow a user to overcome the interference or frictional fit and separate the accessory 104 and protective device 102. In some embodiments, a liner (see FIG. 8), detents (see FIG. 3), a clasp, a latch, tabs and slots, or some other feature, or any combination of the foregoing, may be utilized and may be selectively disengaged or overcome to allow separation of the accessory 104 from the protective device 102. Of course, the accessory 104 may also be reengaged or reattached to the protective device 102 using the same mechanism that is overcome when removing the accessory 104.

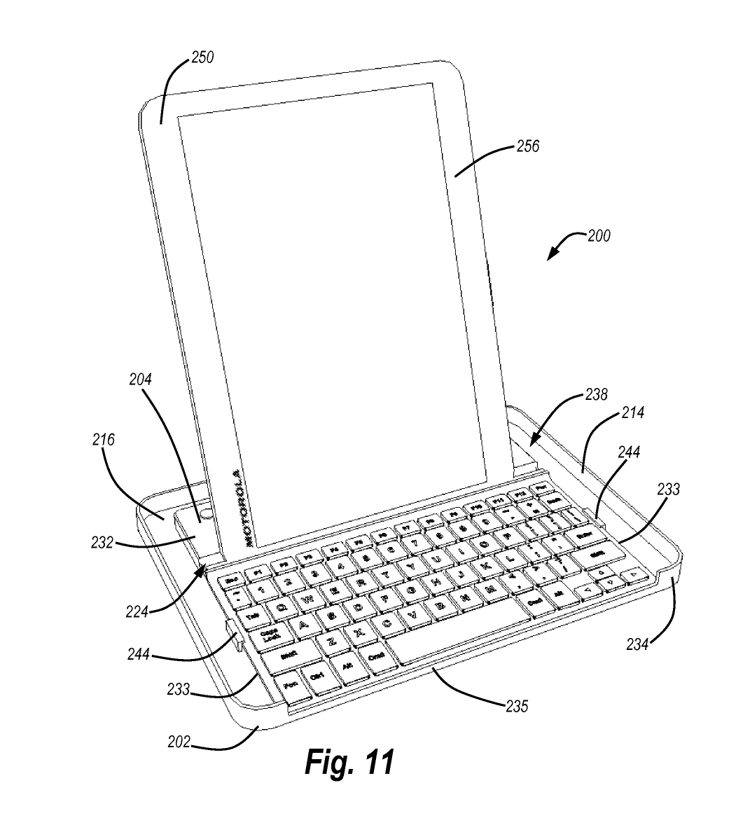

Turning now to FIGS. 10 and 11, an embodiment of a protective system 200 that includes a protective device 202 and an accessory 204 is illustrated. The protective device 202, as shown, is another case. The protective device 202 and the accessory 204 may include features similar to those discussed above relative to the protective device 102 and the accessory 104. Accordingly, elements and features described herein should be considered to be interchangeable, and can be utilized in any embodiment disclosed herein.

In the embodiment shown in FIGS. 10 and 11, the accessory 204 includes a support element 206 and a keyboard 208. One or more dimensions (e.g., height, width, etc.) of the accessory 204 may be smaller than the corresponding dimensions of the protective device 202 and, optionally, of a portable electronic device 250 with which the protective device 202 is configured to be used.

To enable support for a portable electronic device with a dimeions (e.g., height, width, etc.) larger than the accessory 204, the illustrated embodiment depicts the support element 206 as being open each of its ends. In this embodiment, the ends of the support element 206 generally correspond to the positions of the side surfaces 233 of the accessory 206. Because the support element 206 is open at one or more of its respective sides, a portable electronic device 250 may be placed relative to the support element 206, and even slid or otherwise moved with respect thereto, without being limited by one or more closed end surfaces.

In addition to accommodating devices of different widths and/or lengths, the accessory 204 may also be used in connection with devices of different thicknesses. For instance, without limiting the present disclosure, the support element 206 may define a channel 224 or other feature into which a portion of the portable electronic device 250 is situated or otherwise located. The width of the corresponding channel 224 may be greater than the width of the particular device then being supported. For instance, the support element 206 may define a channel 224 that is between about one-quarter inch (about 6.35 mm) and about one inch (about 25.40 mm) in width, although in other embodiments the channel 224 may be larger or smaller, as appropriate. In any event, a device having a thickness less than the width of the channel 224 may be positioned within the channel and supported.

By way of illustration, where support element 206 defines a channel 224 or other feature that is wider than a thickness of the portable electronic device 250, the support element 206 may orient the portable electronic device 250 at a non-perpendicular, inclined angle relative to the accessory 204. As discussed above, such a support element 206 may enable the portable electronic device 250 to be received in a leveraged orientation in which two offset contacts create a mechanical advantage that stabilizes the portable electronic device 250. Of course, the support element 206 may be otherwise configured to orient a portable electronic device 250 at a particular angle, For instance, a configuration of the support element 206 may orient a portable electronic device 250 in a desired manner. Alternatively, various removable or permanent inserts (not shown) may be sized to fit within a groove or channel 224 of the depicted embodiment of support element 206, or to otherwise operate in connection with the support element 206. Each insert may be configured to orient a portable electronic device 250 in a desired manner. Alternatively, inserts may be tailored for use with particular types or configurations of portable electronic devices 250. In some embodiments, the support element 106 may have different widths at different locations along its length.

The accessory 204 may thus be configured to support any of one or more different portable electronic devices 250 in at least partially upright orientations using any number of different mechanisms. For instance, FIGS. 10 and 11 illustrate the portable electronic device 250 in respective landscape and portrait orientations. In each such embodiment, the portable electronic device 250 is in a working arrangement. The angle at which the portable electronic device 250 is oriented may be adjusted based on various factors, including the size (e.g., thickness, width, etc.) of the portable electronic device 250, the width of the location of the support element 206 where the portable electronic device 250 is positioned, the orientation of the support element 206 (e.g., vertical, inclined, etc.), the use of an insert with the support element 206, and the like. Accordingly, embodiments of accessories 204 consistent with the disclosure herein can be utilized in connection with any of various different portable electronic devices, each of which may have a different length, width, thickness, aspect ratio, etc.

As further shown in FIGS. 10 and 11, the accessory 204 and portable electronic device 250 may be utilized in connection with a protective device 202. Without limiting the disclosure herein, the protective device 202 may, in some embodiments, be configured to cover or otherwise protect the display 251 on a front side 256 of the portable electronic device 250. More particularly, in accordance with at least one example embodiment, the protective device 202 includes at least one retention element 234 configured to retain the portable electronic device 250 in a storage configuration. The retention element 234, which may be similar to the retention element 134 of FIGS. 1-9, may engage part (e.g., a peripheral edge, a feature, etc.) of the portable electronic device 250 and facilitate retaining or securement of the portable electronic device 250 to the protective device 202. In some embodiments, the retention element 234 may also secure the accessory 204 to the protective device 202. For instance, the accessory 204 may be sized to generally correspond to the size and shape of the protective device 202 so as to fit securely within a receptacle 238 defined by the retention element 234 and a base 216 of the protective device 202.

In other embodiments, such as those illustrated in FIGS. 10 and 11, the accessory 204 may not be configured (e.g., due to its size, shape, or other configuration) for use with the retention element(s) 234 of the protective device 202. More specifically, in the illustrated embodiment, the accessory 206 has a width and length less than a corresponding width and length of the retention element 234 of the protective device 202. Accordingly, secondary retention elements 244 may protrude from the base 216 of the protective device 202, within its interior, or otherwise be positioned, sized, or otherwise configured to secure the accessory 204 in place relative to the protective device 202. The secondary retention elements 244 may take any number of forms. For instance, the secondary retention elements 244 may include posts, guides, clips, snap-fits, or any other suitable structure. Further, in some embodiments, portions of the retention element(s) 234 may be used in conjunction with the secondary retention elements 244 to collectively retain the accessory 204 in place at a particular position or orientation with respect to the protective device 202. More particularly, the retention element 234 of the illustrated embodiment includes a frontal wall 235. The accessory 204 may be placed against the frontal wall 235 and otherwise secured by secondary retention elements 244. In this embodiment, secondary retention elements 244 may extend along all or a portion of the sides 233 of the accessory 204 and/or along a rear side 237 of the accessory 204.

Regardless of the size of the accessory 204 relative to the protective device 202 and/or the retention element 234, the protective device 202 may be utilized to secure the portable electronic device 250 in a stored configuration or state. For instance, the receptacle 238 as defined by the base 216 and the retention element 234 may generally correspond in size and/or shape to the size and shape of the portable electronic device 250. As the portable electronic device 250 is placed into the receptacle 238 (e.g., display-side up or down), the peripheral edges or other features of the portable electronic device 250 may engage one or more interior surfaces 214 of the retention element 234. An interference fit, frictional fit, or other securement mechanism may be used such that the portable electronic device 250 is removably secured to the protective device 202.

The accessory 204 may also be removable from the protective device 202. For instance, the secondary retention elements 244 may be at least partially flexible or otherwise structured so as to allow the accessory to be removed therefrom. Moreover, while the secondary retention elements 244 are illustrated as protruding from the base 216, such is merely an example embodiment. In other embodiments, one or more secondary retention elements may be attached or otherwise secured relative to the retention elements 234 (e.g., extending from interior surface 214). The secondary retention elements 244 may also be movable and/or removable. In one embodiment, for instance, the secondary retention elements 244 may include a removable insert that is sized to generally correspond to the size and shape of the receptacle 238. The insert may provide an opening generally corresponding to the size, shape, or other configuration of the accessory 204. The illustrated secondary retention devices 244 may also be removable or moveable. Such retention devices 244 may, for instance, include a release mechanism (e.g., a slot-and-tab, a snap fit, etc.) or may pivot so as to be closeable. The secondary retention devices 244 may also be moveable to be positioned in different locations. In such an embodiment, the retention devices 244 may be moved to accommodate multiple accessories at a time, or to accept and secure different accessories of varying sizes or shapes.

As noted previously herein, in accordance with one embodiment, and without limiting the scope of the present disclosure, the peripheral element 234 may include multiple sides or other surfaces, including a side 235 adjacent to the keyboard 208. While the side 235 may have a height consistent with other sides of the peripheral element 234, in the illustrated embodiment the side 235 has a recessed or otherwise reduced height relative to other portions of the retention element 234. Such a recess or other feature may be located at an elevation that corresponds to an elevation of the keys 210 of the keyboard 208 so as to provide improved access to the keyboard 208. In the same or other embodiments, the portable electronic device 250 and/or the accessory 204 may include features (e.g., buttons, switches, ports, etc.) that may be located adjacent the side 235 when the portable electronic device 250 is in a stored position. The reduced height of the side 235 may allow such features to extend outside the receptacle 238 and/or to be accessible while the portable electronic device 250 is in a stored or working arrangement.

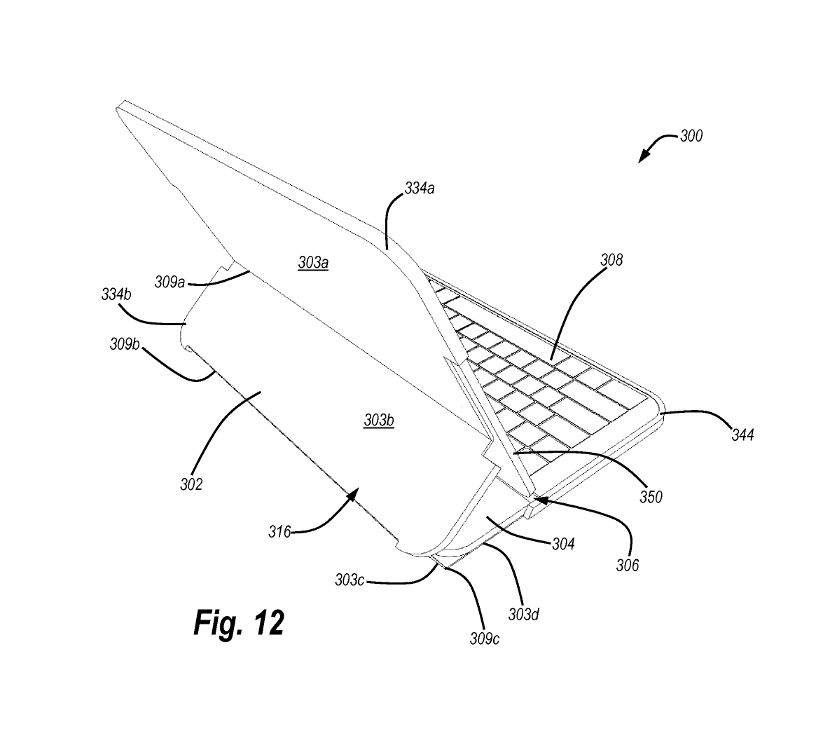

While the protective system 200 may be rigid or substantially rigid, embodiments of the present disclosure extend to embodiments in which a protective system 200 is at least partially flexible. More particularly, FIGS. 12-15 illustrate embodiments of an example protective system 300 configured to bend or flex at least at predefined locations, while also being configured to support a portable electronic device 350 in an upright, working arrangement.

In particular, FIGS. 12-15 illustrate embodiments of a protective device 302 that may fold or bend to form a folio-type protective system 300. In the illustrated embodiment, the protective device 302 includes a base 316 formed of multiple sections 303a-e. The sections 303a-e may take any of numerous forms. Generally, the sections 303a-e may interface or be linked in some manner and each section 303a-e may be configured to move relative to one or more of the other sections 303a-e. In some embodiments, each of the sections 303a-e is flexible to facilitate such movement. In other embodiments, one or more sections 303a-e are substantially rigid. For instance, in at least one embodiment, all or a majority of the sections 303a-e are substantially rigid, and a living hinge or flexible fabric or other interface connects different sections 303a-e. In one non-limiting example, a linking section 303c may be at least partially flexible while the sections 303a, 303b, 303d, 303e are substantially rigid.

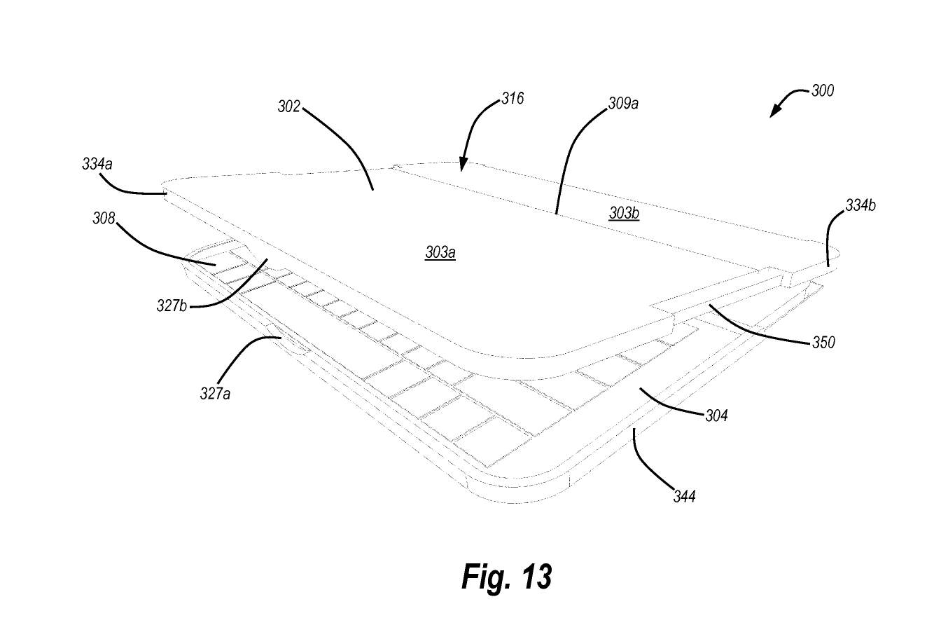

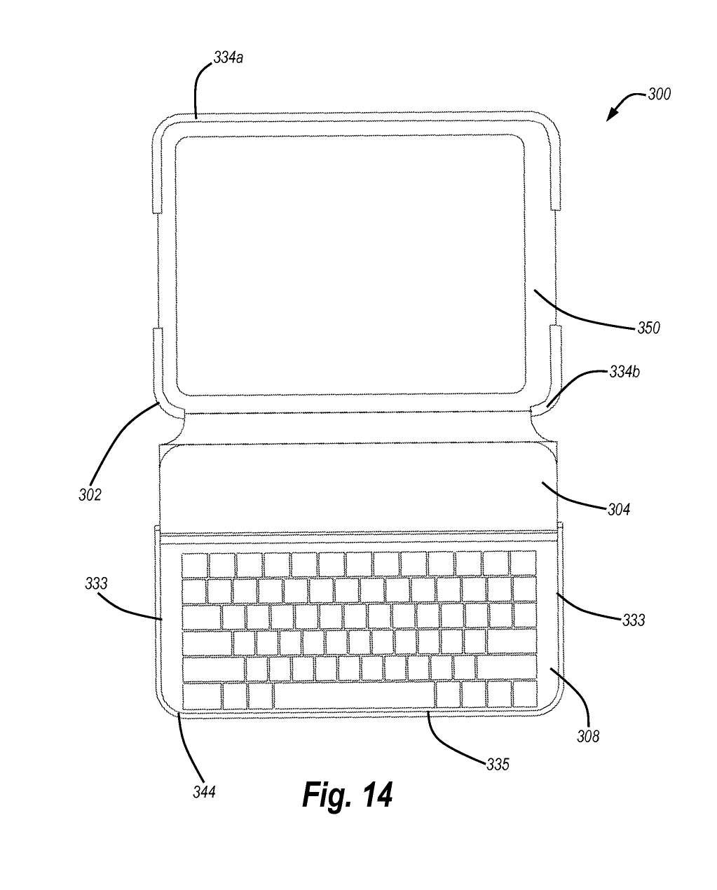

Even in embodiments in which one or more, and possibly all, of the sections 303a-e are rigid or substantially rigid, the sections 303a-e may move relative to each other. By way of illustration, the illustrated embodiments depict a set of at least three interfaces 309a-e interfacing between the various sections 303a-e. More particularly, the interface 309a may connect sections 303a and 303b, while interfaces 309b and 309c may connect the section 303c to sections 303b and section 303d, respectively. As noted above, the interfaces 309a-c may be flexible in some embodiments. Such interfaces 309a-c may include, for instance, pivots, hinges, living hinges, flexible fabric or other materials, or other features, or any combination thereof. The interfaces 309a-c may be sufficiently flexible that the panels 303a-e may move between multiple configurations or states such as those shown in FIGS. 12-14. More particularly, FIG. 12 illustrates a working arrangement, while FIGS. 13 and 14 illustrate closed (i.e., protetcted) and open arrangements, respectively.

With respect to FIGS. 12-14, it will be appreciated that the protective system 300 may be configured to receive one or more of a portable electronic device 350 or an accessory 304. For instance, an accessory 304 may comprise a keyboard 308, although the accessory 304 may include other or additional types of peripheral components. Optionally, the protective device 302 may arrange the portable electronic device 350 and the accessory 304 in a manner that protects one or both of the portable electronic device 350 and the accessory 304, and that facilitates use of the accessory 304 and/or the portable electronic device 350 in at least one particular manner.

To facilitate use of the protective device 302 with the portable electronic device 350, the protective device 302 may include one or more retention elements 334a, 334b. In at least some embodiments, the retention elements 334a, 334b are configured to connect to the portable electronic device 350 and at least temporarily maintain the accessory 304 and the portable electronic device 350 in a particular position. By way of illustration, the retention elements 334a, 334b may comprise slots and/or corners that are configured to receive and retain complementarily configured features (e.g., the peripheral edges, etc.) of the accessory 304 and/or the portable electronic device 304. Of course, other configurations of retention elements 334a, 334b may also be used. In the illustrated embodiment, the retention elements 334a, 334b, include peripheral side surfaces that extend outward and about perpendicular relative to corresponding sections 303a, 303b of the base 316. Such peripheral side surfaces are optionally rigid, and can be sized and shaped to receive and/or otherwise engage peripheral sides of the portable electronic device 350. In at least one embodiment, a groove 337 may extend through all or a portion of the retention elements 334a, 334b. The groove 337 may have a width generally corresponding to the thickness of the portable electronic device 350, thereby allowing the portable electronic device 350 to be situated within (e.g., slide along, etc.) the groove 337 and to be secured by the retention elements 334a, 334b using a frictional or other fit.

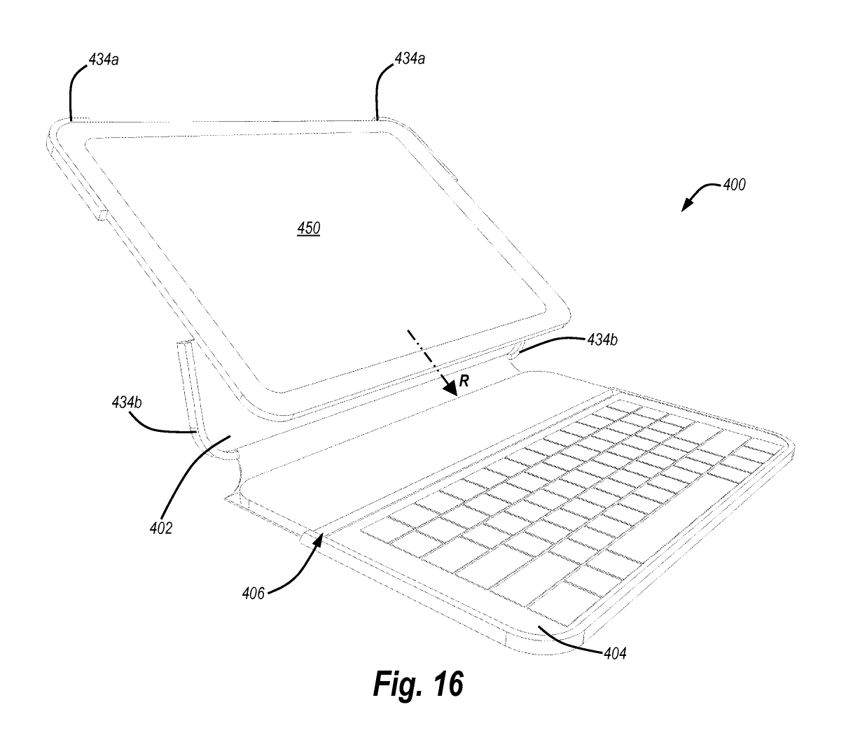

Although the embodiments illustrated in FIGS. 12-15 illustrate the retention element 334a as generally being continuous, it should be appreciated that such embodiment is merely an example. In other embodiments, such as in FIG. 16 for instance, a retention element may be segmented. Each individual segment may be attached to a particular portion of the portable electronic device 350. For instance, certain segments may attach to side, corner, or top or bottom edges, while a separation between such segments provides openings. Such openings are optionally coordinated to correspond to locations of ports, switches, buttons, expansion slots, etc. of the portable electronic device 350. Additionally, while the retention element 334b is illustrated as being segmented so as to correspond generally to corners of the portable electronic device 350, such embodiment is also merely illustrative. In other embodiments, the retention element 334b may be segmented in other manners, or may be continuous or otherwise configured to be a unitary element extending around a particular portion of the portable electronic device 350, or otherwise connecting to the portable electronic device 350.

In accordance with some embodiments of the present disclosure, the retention elements 334a, 334b may connect to the portable electronic device 350 in different manners or while the protective device 302 and/or portable electronic device 350 are in different positions, configurations, or states. FIGS. 12-14 illustrate some example states of a particular embodiment of the protective system 300. More particularly, in this embodiment, there may be different connections between the portable electronic device 350 and the retention elements 334a, 334b depending on the state or position of the portable electronic device 350.

In particular, with respect to FIG. 12, the portable electronic device 350 is illustrated in a partially upright, working arrangement relative to the accessory 304. In such an embodiment, it will be appreciated that that the retention element 334a—which in the illustrated orientation is an upper retention element—may be secured to one or more upper peripheral portions of the portable electronic device 350. In this embodiment, the upper device section 303a of the base 316 is in a rotated position relative to the lower device section 303b. More particularly, the sections 303a, 303b are illustrated as being rotated relative to each other about the interface 309a. As a result, the sections 303a, 303b are illustrated in a non-parallel relationship. As the portable electronic device 350 of the present embodiment is generally planar, the retention element 334b—which in the illustrated orientation is a lower retention element—is shown as being disengaged from the portable electronic device 350 while the portable electronic device 350 is in the working arrangement.

Also in the illustrated working arrangement, the linking section 303c may be at a rotated position relative to one or more of the sections 303a, 303b, 303d, 303e. In FIG. 12, for instance, the linking section 303c is non-parallel to all other sections of the base 316. More particularly, the interfaces 309b, 309c are flexed or otherwise used in a manner that places the linking section 303c non-parallel at least to the adjacent sections 303b, 303d.

In the illustrated working arrangement, the base 316 may support of the portable electronic device 350 so as to maintain the portable electronic device 350 in an upright position. In particular, as shown in FIG. 12, the portable electronic device 350 may also be supported by the support element 306 of the accessory 304. The support element 306 may be configured in a similar manner to the support elements 106 and 206 disclosed previously herein, and is one example of a means for supporting the portable electronic device 350 in a desired orientation relative to the accessory 304. In the illustrated working arrangement, the sections 303b-d of the base 316 may generally form an angled support structure that, when combined with the rear surface of the portable electronic device 350, is generally triangular or wedge-shaped from a side plan view. In some embodiments, the retention elements 334b may act as support feet that engage a surface on which the protective system 300 is positioned while the portable electronic device 350 is in the working configuration. Accordingly, the retention elements 334b, in combination with the support element 306, are also an example of a means for supporting a portable electronic device in an angled orientation relative to the accessory 304.

The means for supporting the portable electronic device 350 may be sufficient to stabilize the portable electronic device 350 during transport of the protective system 350. For instance, a user may move the system 350 from the user lap to a table, or vice versa. In doing so, the user may grasp the lower portion of the protective cover 402 (e.g., at section 303d, 303e, or retention element 344). The user may thus carry the system 300 to a different location. During such carrying or other transport, the portable electronic device 350 may remain secured in place by the support element 306 so that the user need not also stabilize the portable electronic device 350 independent of the portions of the protective device 302. Such a structure may also stablize the portable electronic device 350 during other movement, such as movement of a person's legs while the system is in that person's lap.

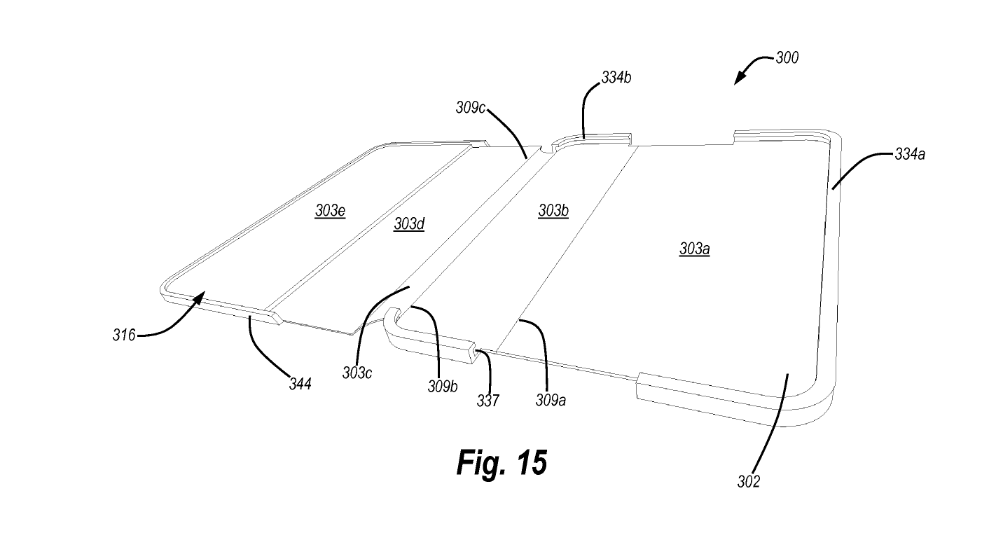

The protective device 302 may be transitioned from the working arrangement to another other arrangement, such as another open arrangement or a closed, protected arrangement. For instance, by disengaging the electronic device 350 from the support element 306 of the accessory 304, the sections 303a, 303b of the base 316 may be rotated or otherwise moved into a parallel and coplanar arrangement. In such an arrangement, the sections 303a, 303b may allow the retention elements 334b to be attached to the portable electronic device 350. The linking section 303c may also be moved about interface 309b and/or interface 309c. For instance, when the linking section 303c is rotated to also be about parallel to and coplanar with the sections 303a, 303b, 303d, 303e of the base, the protective device 302 may be positioned in an open arrangement similar to that illustrated in FIGS. 14 and 15. In contrast, if the linking section 303c is rotated such that sections 303a, 303b are about parallel to, but non-coplanar with, sections 303d, 303e, an alternative arrangement may be obtained. For instance, if the portable electronic device 350 is rotated towards the accessory 304, the sections 303a, 303b may overlap the sections 303d, 303e, as shown in FIG. 13, to produce a closed or storage arrangement. In the storage arrangement, the display or front surface of the portable electronic device 350 may be directed towards and protected by the accessory 306 and/or the sections 303d, 303e of the base 316. Such an orientation may cause the device 350 to shut down or enter into a sleep mode.

In at least some embodiments, the protective system 300 may include one or more elements to facilitate maintaining the protective device 302 in the protected arrangement. In FIG. 13, for instance, the protective cover 302 may include corresponding securement portions 327a, 327b. In particular, in this embodiment, securement portion 327a may include a slot, opening, or other similar structure. The corresponding securement portion 327b may include a tab or other element having a mating structure. When the protective device 302 is fully closed, the portions 327a, 327b may mate to provide a clasp that selectively maintains the protective device 302 closed. The portions 327a, 327b may mate using a frictional, interference, or other engagement. In other embodiments the portions 327a, 327 may also have other structures. For instance, a lip, buckle, resilient member, and/or other structure may be provided to at least temporarily and/or selectively secure the portions of the protective device 302 in a desired orientation or arrangement. It will further be appreciated that instead of rotating the display of the portable electronic device 350 towards the keyboard 308 of the accessory 304 (e.g., to obtain or approach a closed arrangement, etc.), the rear surface of the portable electronic device 350 may instead be rotated towards the back surface of the accessory 304. In such an embodiment, a second open configuration (not shown) may also be obtained.

The protective system 300 optionally includes and/or otherwise operates in connection with an accessory 306. In general, the protective device 302 and the accessory 304 may include features similar to those discussed above relative to other embodiments of protective devices and/or accessories. Accordingly, features illustrated or described relative to FIGS. 1-11 may be included within the embodiments of FIGS. 12-15.

In some embodiments, various sections of the protective device 302 may be sized, shaped, or otherwise configured to account for variations in the accessory 304. For instance, as best illustrated in FIG. 15, the protective device 302 may have adjacent sections 303d, 303e that may be generally parallel, but have upper surfaces that are non-coplanar. In particular, the illustrated section 303e is shown as having a higher elevation than the section 303d. Such difference in elevation may be produced by providing an increased thickness to the section 303e, by providing a transition panel between sections 303d, 303e, or in any other suitable manner. In still other embodiments, sections 303d, 303e may be generally co-planar, or the elevation of the section 303d may be higher than the elevation of the section 303e.

The sections 303d, 303e may be considered accessory sections as they can mate with, connect to, or otherwise be positioned to correspond to an accessory 304 that is used in connection with the protective system 300. The accessory 304 is optionally secured to the protective device 302 in a permanent or removable manner. For instance, the protective device 302 may include a secondary retention element 344 configured to connect to the accessory 304 (e.g., at one or more peripheral sides or edges thereof) and/or to facilitate alignment of the accessory 304 relative to the protective device 302. The secondary retention element 344 can be structured in any suitable manner. For instance, the secondary retention element 344 may include one or more grooves or slots (not shown) configured to receive a corresponding tab or ridge (not shown) in the accessory 304.

In the illustrated embodiment, the secondary retention element 344 is structured as a wall or set of walls that generally extend along a frontal side 335 of the accessory 304, and along at least portions of two lateral sides 333 of the accessory 304. Such structure is, however, merely one example of a suitable structure. In other embodiments, for instance, the secondary retention element 344 may include other components such as clips, latches, tethers, or other devices may be utilized. In the same or other embodiments, a secondary retention element may connect to the base of the accessory 304 rather than to a peripheral edge.

The accessory 304 may also be modular or removable for use with other covers or protective devices, or to allow the protective device 302 to be utilized with any number of different accessories. Accordingly, when disassembly of the accessory 304 from the protective device 302 is desired, a user grasp the accessory 304 and overcome a frictional or interference fit between the accessory 304 and the secondary retention element 344. In other embodiments, a user may adjust a secondary retention element 344 to release the accessory 304. In such case, the user may thereafter remove the accessory 304 such that sections 303d, 303e may no longer support the accessory 304, as shown in FIG. 15.

FIG. 16 illustrates an embodiment of a protective system 400 similar in many regards to the protective system 300 illustrated by and described in reference to FIGS. 12-15. Accordingly, a protective device 402 may be secured to a portable electronic device 450 and an optional accessory 404 and be changeable between various arrangements. The accessory 404 may include a support structure 406 that can be used to hold or otherwise maintain the portable electronic device 450 in a particular orientation (e.g., upright, at a non-perpendicular inclined angle, etc.).

In this embodiment, the portable electronic device 450 is secured to the protective device 402 using a set of retention elements 434a positioned at corresponding upper corners of the portable electronic device 450. The retention elements 434a may be configured to provide an interference, frictional, or other fit that can engage and be secured to the portable electronic device 450. In one embodiment, the retention elements 450 may define a slot or channel (not shown) into which the portable electronic device 450 may be positioned. Whether or not a slot or channel is removed, a user may be able to selectively remove the portable electronic device 450 from the protective device 402. For instance, a user may slide the portable electronic device in the direction indicated by arrow R. Such motion may remove the portable electronic device 450 from a slot or channel, or otherwise overcome or remove a securement between the retention elements 434a, 434b and the portable electronic device 450. The portable electronic device 450 may be connected to the retention elements 434a in an opposing manner, by sliding the portable electronic device in a direction opposite that of arrow R. In some embodiments, elements 434b (which optionally act as secondary retention elements or as protective elements), may be disconnected from the portable electronic device 450 when the portable electronic device 450 is removed and/or when connected to the retention elements 434a.

As will be appreciated in view of the disclosure herein, the protective device 402 (and protective device 302) may securely hold the electronic device 450 in place even without substantially obscuring a display or front surface of the device. For instance, in some embodiments, the retention elements 434a may not cover any of the front surface of the electronic device 450. In other embodiments, the retention elements 434a and/or elements 434b may connect to the electronic device and overlap the front surface. Such overlap may be between 1 millimeter and 1 centimeter in some embodiments.

Although the foregoing description provides many specifics, these should not be construed as limiting the scope of any of the appended claims, but merely as providing information pertinent to some specific embodiments that may fall within the scopes of the appended claims. Features from different embodiments may be employed in combination. In addition, other embodiments may also be devised which lie within the scopes of the appended claims. The scopes of the claims are, therefore, indicated and limited only by their language the legal equivalents to their elements. All additions, deletions and modifications to the disclosed subject matter that fall within the meaning and scopes of the claims are to be embraced by the claims.

What is claimed:

1. A protective system for a portable electronic device, comprising:
a protective device configured to be selectively positioned over a display of a portable electronic device when the portable electronic device is in a protected arrangement; and
an accessory associated with the protective device, wherein the accessory includes a support element defining an opening configured to receive at least a portion of the portable electronic device when the portable electronic device is in a working arrangement.

2. The protective system of claim 1, wherein the accessory is removably secured to the protective device.

3. The protective system of claim 1, wherein the opening includes a lateral channel within the accessory.

4. The protective system of claim 1, wherein the opening is oriented at an angle relative to the accessory.

5. The protective system of claim 4, wherein the angle is between about five degrees and about thirty degrees.

6. The protective system of claim 1, wherein a width of the opening is between about 0.25 inch and about 1.0 inch.

7. The protective system of claim 1, wherein the accessory is configured to self-support the portable electronic device without the use of supplemental support elements.

8. The protective system of claim 1, wherein the support element does not include movable parts for supporting the portable electronic device.

9. The protective system of claim 1, wherein the protective device includes one or more access features configured to provide access to one or more features on the accessory or the portable electronic device.

10. The protective system of claim 9, wherein the one or more access features are configured to provide access to one or more features of the portable electronic device while the portable electronic device is in the protected arrangement.

11. The protective system of claim 1, wherein the opening is open at a top surface and one or more side surfaces of the accessory.

12. The protective system of claim 1, wherein the accessory includes a keyboard.

13. A protective cover for a portable electronic device, comprising:
a protective cover configured to protect at least a portion of a portable electronic device; and
an accessory connected to the protective cover, the accessory including a means for supporting the portable electronic device in an angled orientation.

14. The protective cover of claim 13, wherein the protective cover is a rigid cover configured to receive at least a portion of the accessory and at least a portion of the portable electronic device when a display of the portable electronic device is in a protected arrangement.

15. The protective cover of claim 14, wherein the rigid cover includes a plurality of connected rigid panels.

16. The protective cover of claim 13, wherein the means for supporting the portable electronic device is configured to support a device having a dimension larger than a width of the accessory.

17. The protective cover of claim 13, wherein the means for supporting the portable device is configured to support the portable electronic device at an angle between about zero degrees and about forty-five degrees relative to an axis normal to the accessory.

18. The protective cover of claim 13, wherein the accessory includes one or more of: a keyboard; an audio output; an audio input; a scanner; a printer; or a storage device.

19. The protective cover of claim 13, the protective cover including a resilient lining configured to retain the accessory and the portable electronic device secured thereto.

20. A method for protecting a portable electronic device, comprising:
removing a portable electronic device from a working arrangement in which the portable electronic device is inclined within a channel of a accessory configured to communicate with the portable electronic device; and
placing the portable electronic device in a stored arrangement in which a display of the portable electronic device is at least partially covered by at least one of the accessory or a protective cover connected to the accessory.

21. The method recited in claim 20, wherein in the working arrangement, the portable electronic device is positioned at an angle leveraging the portable electronic device within the channel, and wherein leveraging the portable electronic device secures the portable electronic device at an inclined orientation relative to the accessory and the protective cover.

22. A protective system, comprising:
a computing accessory, the computing accessory including:
a keyboard;
a coupling element configured to support a portable electronic device in an at least partially upright configuration; and
at least one communication element configured to establish communication between the keyboard and the portable electronic device; and
a protective device configured to connect to the computing accessory and the portable electronic device, the protective device including:
a first connection portion configured to engage the portable electronic device; and
a second connection portion configured to engage the computing accessory

23. The protective system of claim 21, further comprising the portable electronic device.

24. The protective system of claim 21, wherein a fold or hinge exists between the first connection portion and the second connection portion.

25. The protective system of claim 21, herein wherein the first connection portion includes two corner and siderail connectors;

26. The protective system of claim 24, wherein the corner and siderail connectors are configured to allow the portable computing device to slideably be secured thereto and removed therefrom.

27. The protective system of claim 21, wherein the coupling element includes a slot configured to secure the portable electronic device at an inclined position.

28. The protective system of claim 21, wherein the first connection portion is configured to cover at most an insubstantial portion of a front surface of the portable electronic device.

29. The protective system of claim 27, wherein the first connection portion overlaps the front surface by an amount between about 0 millimeters and about 25 millimeters.

30. The protective system of claim 21, wherein the protective device includes a clasp configured to hold the first and second connection portions in a folded, closed arrangement.

31. The protective system of claim 29, wherein a first clasp portion is located on the first connection portion and a second clasp portion is located on the second connection portion.
